(19) United States
(12) Patent Application Publication
(10) Pub. No.: US 2009/0167158 A1
(43) Pub. Date: Jul. 2, 2009

(54) Electroluminescent Devices

(76) Inventors: Poopathy Kathirgamanathan, North Harrow (GB); Seenivasagam Ravichandran, London (GB); Yun Fu Chan, Hayes (GB)

Correspondence Address: David Silverstein;Andover-IP-Law, 44 Park Street, Suite 300, Andover, MA, 01810, US

(21) Appl. No.: 12/084,280

(22) PCT Filed: Nov. 7, 2006
(86) PCT No.: PCT/GB2006/050374

§ 371 Date: Apr. 29, 2008

(30) Foreign Application Priority Data
Nov. 7, 2005 (GB) 0522645.1

(51) Int. Cl. H01L 51/54

(52) U.S. Cl. 313/504; 313/506; 313/503

(57) ABSTRACT

In an OLED there is a reflectivity influencing layer (27) which is preferably semi-absorbent and in embodiments is dark coloured or black which is formed of a sublimable organometallic compound. The reflectivity influencing layer is formed between an electrode (29 or 22) and a light-emitting layer (25).

### FIELD OF THE INVENTION

This invention relates to electroluminescent devices which may be based on inorganic, polymeric, metal complex or organometallic electroluminescent materials and have a contrast enhancing layer.

### BACKGROUND TO THE INVENTION

Except where otherwise indicated, the disclosures of all documents mentioned herein are incorporated herein by reference.

Materials which emit light when an electric current is passed through them are well known and used in a wide range of display applications. Liquid crystal devices and devices which are based on inorganic semiconductor systems are widely used. However, these suffer from the disadvantages of high energy consumption, high cost of manufacture, low quantum efficiency and the inability to make flat panel displays.

In one type of electroluminescent device there are successive layers comprising a transparent first electrode e.g. formed of an indium tin oxide coated glass which is the anode, optionally a hole transporting layer, a layer of the electroluminescent material, optionally an electron transmitting layer and a cathode. The cathode is usually a metal such as aluminium or an aluminium containing alloy. When an electric current is passed through the device, light is emitted through the transparent first electrode.

With electroluminescent devices the brightness and clarity of the display depends to a certain extent on the contrast between the background colour and the emitted light. For example in monochromatic displays e.g. used in mobile telephones etc. the readability of messages on the screen depends on the contrast between the brightness of the images and the background. Normally a black background gives the best contrast, but with electroluminescent devices of the type described above some light is reflected from the metal cathode thus reducing this contrast.

Patent application WO 00/350281 describes a light-emissive device comprising: a light-emissive region; a first electrode located on a viewing side of the light-emissive region for injecting charge carriers of a first type; and a second electrode located on a non-viewing side of the light-emissive region for injecting charge carriers of a second type and wherein there is a reflectivity-influencing structure located on the non-viewing side of the light-emissive region and including a light absorbent layer comprising graphite and/or a fluoride or oxide of a low work function metal. This application also describes a light-emissive device comprising: a light-emissive region; a first electrode located on a viewing side of the light-emissive region for injecting charge carriers of a first type and a second electrode located on a non-viewing side of the light-emissive region for injecting charge carriers of a second type and wherein there is a reflectivity-influencing structure located on the non-viewing side of the light-emissive region and including a light-reflective layer and a light-emissive spacing layer between the second electrode and the light-reflective layer, the thickness of the spacing layer being such as to space a reflective plane of the light-reflective layer by approximately half the wavelength of the optical mode of the device from at least part of the light-emissive region. The reflectivity-influencing structure is stated to reduce the reflectance from the second electrode and to improve the efficiency of the device.

The light-emissive region incorporates an electroluminescent material and the materials disclosed are semiconductive and/or conjugated polymer materials. Alternatively the light-emissive material could be of other types, for example sublimed small molecule films or inorganic light-emissive material. The/each organic light-emissive material may comprise one or more individual organic materials, suitably polymers, preferably fully or partially conjugated polymers. Example materials include one or more of the following in any combination: poly(p-phenylenevinylene) (“PPV”), poly(2-methoxy-5(2′-ethyl)hexyloxyphenylene-vinylene) (“MEH-PPV”), one or more PPV-derivatives (e.g. di-alkoxy or di-alkyl derivatives), polyfluorenes and/or co-polymers incorporating polyfluorene segments, PPVs and related co-polymers poly(217-(9,9-di-n-octylfluorene)-(1,4-phenylene-((4-secbutylphenyl)imino)-1,4-phenylene)) (“TFB”), poly(2,7-(9,9-di-n-octylfluorene)-(14-phenylene-((4-methylphenyl)imino)-14-phenylene-((4-methylphenyl)imino)-1,4-phenylene)) (“PFM”), poly(2,7-(919-di-n-octylfluorene)(14-phenylene-((4-methoxyphenyl)imino)-1,4-phenylene-((4-methoxyphenyl)imino)-1,4-phenylene)) (“PFIVIO”), poly(2,7-(9,9-di-n-octylfluorene) (“F8”) or (2,7-(9,9-di-n-octylfluorene)-3,6-Benzothiadiazole) (“RBT”). Alternative materials include small molecule materials such as aluminium quinolate (Alq3).

Other materials which have been proposed as coatings or layers between the cathode and the electroluminescent material are silicon nitrides, silicon carbides, silicon monoxide, chromium oxide/silicon oxide mixtures and chromium oxide silicon oxide mixtures.

However the materials used as an intermediate light absorbing layer can adversely affect the performance of the electroluminescent material. This can be caused by the method of forming the intermediate layer. For example, the known and used reflectivity influencing materials are deposited by sputtering which adversely affects the performance of the EL device. An alternative method is to form the cathode so that it is thin enough to be partially or substantially transmissive to light and to have a light absorbing layer behind the cathode; however this type of structure adversely affects the choice and nature of the cathode which can be used.

### SUMMARY OF THE INVENTION

We have now devised an electroluminescent device with an intermediate light absorbing layer which reduces this problem.

According to the invention there is provided an electroluminescent device which comprises sequentially (i) a transparent first electrode (ii) a layer of an electroluminescent material and (iii) a second electrode and in which there is a layer of a reflectivity influencing material between the second electrode and the layer of the electroluminescent material and in which the reflectivity influencing material is a sublimable compound.

### DISCUSSION OF PREFERRED FEATURES

In use the first electrode acts as the anode and the second electrode acts as the cathode and light is emitted through the anode when an electric current is passed through the device.

The first electrode is preferably a transparent substrate such as is a conductive glass or plastic material which acts as the anode. Preferred substrates are conductive glasses such as indium tin oxide coated glass, but any glass which is conductive or has a conductive layer such as a metal or conductive polymer can be used. Conductive polymers and conductive polymer coated glass or plastics materials can also be used as the substrate.

There can be a layer of an electron transmitting material between the layer of the electroluminescent material and the cathode. This electron transmitting layer can be between the cathode and the light absorbing material or between the layer of the electroluminescent material and the light absorbing material.

The light absorbing material can be formed of an electron transmitting material or can be mixed with the electron transmitting material.

The first electrode is preferably at least partially light-transmissive, most preferably substantially transparent, at least to light of some or all of the wavelengths that can be emitted from the device. The first electrode could, for example, be formed of ITO (indium-tin oxide), TO (tin oxide) or gold. The first electrode is preferably disposed in a viewing direction from the light-emissive region—that is between the light-emissive region and an expected location of a viewer. The first electrode may be in the form of a layer. Where the device includes more than one pixel more than one first electrode could be provided to allow (in co-operation with the second electrode) each pixel to be individually addressed.

The second electrode functions as the cathode and can be any low work function metal e.g. aluminium, calcium, lithium, silver/magnesium alloys, rare earth metal alloys etc. Aluminium is a preferred metal. A metal fluoride such as an alkali metal, rare earth metal or their alloys can be used as the second electrode for example by having a metal fluoride layer formed on a metal.

There can optionally be layers of other compounds e.g. LiF which improve the functioning of the device such as buffer layers.

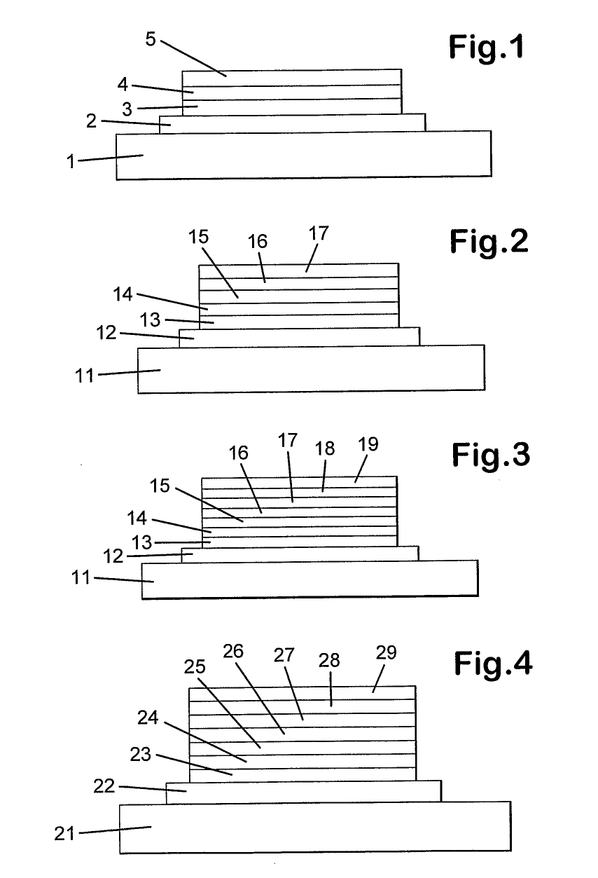

Devices of the present invention are illustrated in FIGS. 1-4 of the drawings.

FIG. 1 shows the cross-sectional structure of an organic electroluminescent device. The device is fabricated on a glass substrate (1) coated with a transparent indium-tin-oxide (“ITO”) layer (2) to form the anode. The ITO-coated substrate is covered with at a layer (3) of a thin film of an electroluminescent and a layer of light absorbing material (4) and an aluminium electrode (5).

FIG. 2 shows a cross-sectional structure of another organic electroluminescent device incorporating other layers and comprises a glass substrate (11) coated with a transparent indium-tin-oxide (“ITO”) layer (12) to form the anode. The ITO-coated substrate is covered with at a layer (13) of a hole transporting material, a layer (14) of a thin film of an electroluminescent material, a layer (15) of light absorbing material, a layer (16) of an electron transmitting material, and an aluminium cathode (17).

In use a current is passed through the device and light emitted out through the glass layer (1) or (11). To a viewer looking at the display the layer (4) or (16) has a black appearance affording a good contrast with the light.

FIG. 3 shows a cross-sectional structure of a further organic electroluminescent device incorporating other layers. It comprises a glass substrate (11) coated with a transparent indium-tin-oxide (“ITO”) layer (12) to form the anode. The ITO-coated substrate is covered with at a layer (13) of a buffer layer, a layer (14) of a hole transporting material, a layer (15) of a thin film of an electroluminescent material, a layer (16) of an electron transmitting material, a layer (17) of a light absorbing material, a layer (18) of a metal fluoride e.g. lithium fluoride, and an aluminium cathode (19).

FIG. 4 shows a cross-sectional structure of a yet further organic electroluminescent device incorporating other layers. It comprises a glass substrate (21) coated with a transparent indium-oxide (“ITO”) layer (22) to form the anode. The ITO-coated substrate is covered with at a layer (23) of a buffer layer hole transporting material, a layer (24) of a hole transporting material thin film, a layer (25) of a thin film of an electroluminescent material, a layer (26) of an electron transmitting material, a layer (27) of a light absorbing material, a layer (28) of a metal fluoride e.g. lithium fluoride and an aluminium cathode (29).

Where the reflectivity influencing layer (host or dopant) is closer to the anode (ITO layer) than the electroluminescent layer (host plus dopant) it is preferably physically separated from it by at least one intervening layer e.g. a hole transport layer. Where the reflectivity influencing layer (host or dopant) is closer to the cathode (aluminium or other metallic layer) than the electroluminescent layer (host plus dopant) it is preferably physically separated from it by at least one intervening layer e.g. an electron transport layer or a hole blocker layer and an electron transport layer. The reason in both cases is to prevent the reflectivity influencing layer from reducing the effectiveness of the electroluminescent layer e.g. by quenching.

The invention may be applied to OLEDs in monochrome displays. Alternatively it may be applied to colour displays having e.g. red, green and blue pixels, the reflectivity influencing layer being common to the pixels of the three different types.

### Reflectivity Influencing Materials

Preferably the reflectivity influencing material is light absorbing so it is semi-absorbing and in some embodiments appears black or nearly black.

By sublimable is meant that the compound will go from the solid to vapour state (or for this application have an intermediate molten phase) when heated without decomposition or other chemical change and will deposit as the solid when condensed on a substrate. Preferably the compounds sublime at a temperature of up to 400° C., more preferably of up to 250° C. under reduced pressure, e.g. down to vacuum, if required, so normal vapour deposition equipment can be used.

The sublimable reflectivity influencing materials which can be used include metal complexes of formula M(DBM)ₓ where M is a transition metal such as chromium, copper, tin (II), tin(IV), lead, palladium, platinum, nickel and x is the valence state of M, and DBM is dibenzoyl methane; metal fluorides metal phthalocyanines such as lithium, copper, magnesium barium, titanyl, vanadyl and zirconyl phthalocyanine; metal complexes of C60 where C60 refers to the so-called buckminsterfullerenes or “buckyballs”, such as manganese, magnesium, calcium, barium, sodium, potassium, rubidium, caesium C60 compounds etc. Other organic metallic complexes which can be used are conductive organic compounds such as metal complexes of tetracyanoquinidodimethane

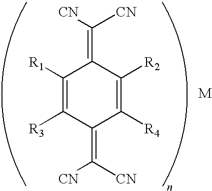

where M is a metal n is the valence state of M and R₁, R₂, R₃ and R₄ are hydrogen, F or the same or different hydrocarbyl or substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine or thiophenyl groups; R₁, R₂ and R₃ can also form substituted and unsubstituted fused aromatic, heterocyclic and polycyclic ring structures and can be copolymerisable with a monomer.

Other sublimable reflectivity influencing materials which can be used include metal quinolates such as Mqₙ where M is a metal or metal oxide such as Cu (II) Sn(II), Sn(IV), Cr(III), NbO, VO, TaO (Group VB) etc. and n is the valency of M. The quinolates are metal complexes of 8-hydroxy quinoline and substituted 8-hydroxy quinolines. Other quinolates which can be used are rare earth quinolate complexes such as Euq₃(bathophenanthroline) and Euq₃(phenanthroline). Copper quinolate in particular has a favourable combination of properties because is readily sublimable, has good light absorption properties when in a thin film, has an absorption peak at about 450 nm with an absorption edge around 500 nm (band gap about 2.4 electron volts), favourable refractive index and does not interfere with the operation of the other layers of the cell. It is process-compatible with the manufacture of OLEDs by vacuum deposition e.g. a satisfactory evaporation rate can be achieved around 230° C. which is relatively low compared to other compounds used in OLED manufacture.

Further examples are rare earth phthalocyanines which are black and conductive and any conductive mixed valence complexes such as Cu(I)Cu(II) L₃ where L is as specified below e.g. Lα.

### Electroluminescent Materials in General

In principle any electroluminescent material may be used, including inorganic materials, polymeric materials, inorganic complexes and organometallic compounds.

Inorganic materials include e.g. Group II/VI compounds such as ZnS:dopants and Group III/V compounds e.g. GaAs.

In particular the invention contemplates the use of a reflection influencing layer e.g. a semi-absorbing layer in combination with a light-emitting polymer. Such organic electroluminescent materials include conducting (conjugated) polymers e.g. PPV (see below) and molecular solids which may be fluorescent dyes e.g. perylene dyes, metal complexes e.g. Alq₃, Ir(III)L₃, rare earth chelates e.g. Tb(III) complexes and oligomers e.g. sexithipphene.

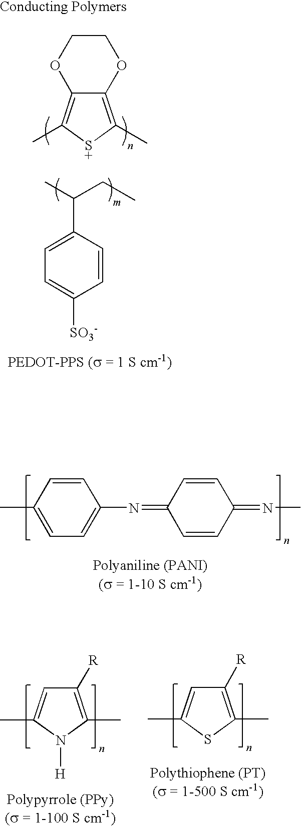

A preferred class of electroluminescent materials includes host materials which may be metal complexes or conjugated aryl or heteroaryl materials e.g. the materials shown below. For example, metal quinolates such as aluminium quinolate or zirconium quinolate may be doped with fluorescent materials or dyes as disclosed in patent application WO 2004/058913.

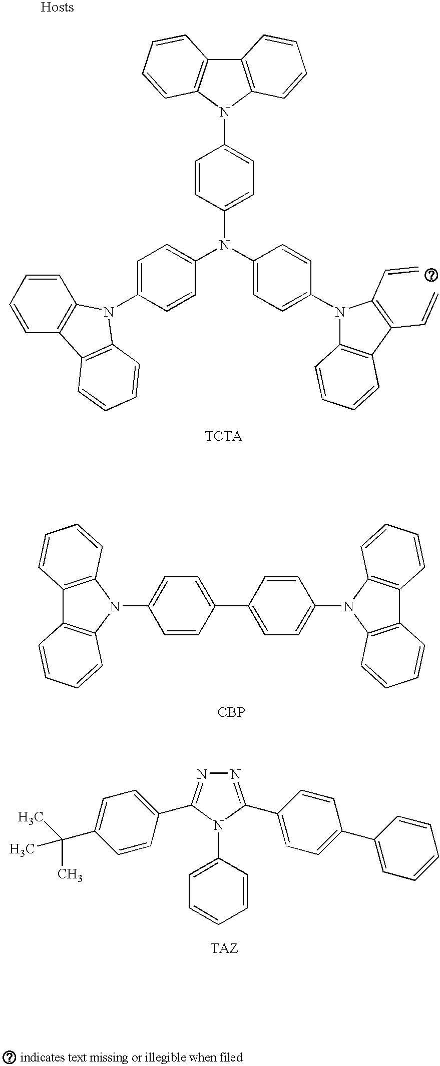

Preferably the host is doped with a minor amount of a fluorescent material as a dopant, preferably in an amount of 5 to 15% by weight of the doped mixture. As discussed in U.S. Pat. No. 4,769,292, the contents of which are included by reference, the presence of the fluorescent material permits a choice from amongst a wide latitude of wavelengths of light emission. In particular, as disclosed in U.S. Pat. No. 4,769,292 by blending with the organo metallic complex, a minor amount of a fluorescent material capable of emitting light in response to hole-electron recombination, the hue of the light emitted from the luminescent zone, can be modified. In theory, in the present application if a host material and a fluorescent material could be found for blending which have exactly the same affinity for hole-electron recombination, each material should emit light upon injection of holes and electrons in the luminescent zone. The perceived hue of light emission would be the visual integration of both emissions. However, since imposing such a balance of host material and fluorescent materials is highly limiting, it is preferred to choose the fluorescent material so that it provides the favoured sites for light emission. When only a small proportion of fluorescent material providing favoured sites for light emission is present, peak intensity wavelength emissions typical of the host material can be entirely eliminated in favour of a new peak intensity wavelength emission attributable to the fluorescent material. While the minimum proportion of fluorescent material sufficient to achieve this effect varies, in no instance is it necessary to employ more than about 10 mole percent fluorescent material, based of host material and seldom is it necessary to employ more than 1 mole percent of the fluorescent material. On the other hand, limiting the fluorescent material present to extremely small amounts, typically less than about 10⁻³ mole percent, based on the host material, can result in retaining emission at wavelengths characteristic of the host material. Thus, by choosing the proportion of a fluorescent material capable of providing favoured sites for light emission, either a full or partial shifting of emission wavelengths can be realized. This allows the spectral emissions of the EL devices to be selected and balanced to suit the application to be served.

Choosing fluorescent materials capable of providing favoured sites for light emission, necessarily involves relating the properties of the fluorescent material to those of the host material. The host can be viewed as a collector for injected holes and electrons with the fluorescent material providing the molecular sites for light emission. One important relationship for choosing a fluorescent material capable of modifying the hue of light emission when present in the host is a comparison of the reduction potentials of the two materials. The fluorescent materials demonstrated to shift the wavelength of light emission have exhibited a less negative reduction potential than that of the host Reduction potentials, measured in electron volts, have been widely reported in the literature along with varied techniques for their measurement. Since it is a comparison of reduction potentials rather than their absolute values which is desired, it is apparent that any accepted technique for reduction potential measurement can be employed, provided both the fluorescent and host reduction potentials are similarly measured. A preferred oxidation and reduction potential measurement techniques is reported by R. J. Cox, Photographic Sensitivity, Academic Press, 1973, Chapter 15.

A second important relationship for choosing a fluorescent material capable of modifying the hue of light emission when present in the host is a comparison of the bandgap potentials of the two materials. The fluorescent materials demonstrated to shift the wavelength of light emission have exhibited a lower bandgap potential than that of the host. The bandgap potential of a molecule is taken as the potential difference in electron volts (eV) separating its ground state and first singlet state. Bandgap potentials and techniques for their measurement have been widely reported in the literature. The bandgap potentials herein reported are those measured in electron volts (eV) at an absorption wavelength which is bathochromic to the absorption peak and of a magnitude one tenth that of the magnitude of the absorption peak. Since it is a comparison of bandgap potentials rather than their absolute values which is desired, it is apparent that any accepted technique for bandgap measurement can be employed, provided both the fluorescent and zirconium 2-methyl quinolate bandgaps are similarly measured. One illustrative measurement technique is disclosed by F. Gutman and L. E. Lyons, Organic Semiconductors, Wiley, 1967, Chapter 5.

With host materials which are themselves capable of emitting light in the absence of the fluorescent material, it has been observed that suppression of light emission at the wavelengths of emission characteristics of the host alone and enhancement of emission at wavelengths characteristic of the fluorescent material occurs when spectral coupling of the host and fluorescent material is achieved. By “spectral coupling” it is meant that an overlap exists between the wavelengths of emission characteristic of the host alone and the wavelengths of light absorption of the fluorescent material in the absence of the host. Optimal spectral coupling occurs when the emission wavelength of the host is ±25 nm of the maximum absorption of the fluorescent material alone. In practice advantageous spectral coupling can occur with peak emission and absorption wavelengths differing by up to 100 nm or more, depending on the width of the peaks and their hypsochromic and bathochromic slopes. Where less than optimum spectral coupling between the host and fluorescent materials is contemplated, a bathochromic as compared to a hypsochromic displacement of the fluorescent material produces more efficient results.

Useful fluorescent materials are those capable of being blended with the quinolate or other host and fabricated into thin films satisfying the thickness ranges described above forming the luminescent zones of the EL devices of this invention. While crystalline organometallic complexes do not lend themselves to thin film formation, the limited amounts of fluorescent materials present in the host permits the use of fluorescent materials which are alone incapable of thin film formation. Preferred fluorescent materials are those which form a common phase with the host. Fluorescent dyes constitute a preferred class of fluorescent materials, since dyes lend themselves to molecular level distribution in the host. Although any convenient technique for dispersing the fluorescent dyes in the host can be undertaken, preferred fluorescent dyes are those which can be vacuum vapour deposited along with the host materials.

Assuming other criteria, noted above, are satisfied, fluorescent laser dyes are recognized to be particularly useful fluorescent materials for use in the organic EL devices of this invention. Dopants which can be used include diphenylacridine, coumarins, perylene and their derivatives. Useful fluorescent dopants are disclosed in U.S. Pat. No. 4,769,292. One class of preferred dopants is coumarins such as those of formula

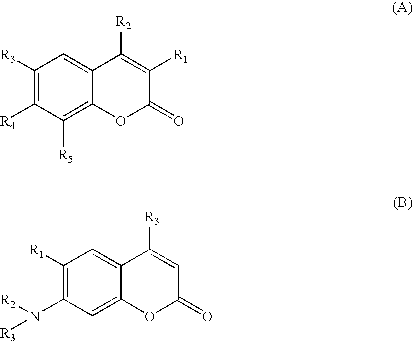

where R₁ is chosen from the group consisting of hydrogen, carboxy, alkanoyl, alkoxycarbonyl, cyano, aryl, and a heterocylic aromatic group, R₂ is chosen from the group consisting of hydrogen, alkyl, haloalkyl, carboxy, alkanoyl, and alkoxycarbonyl, R₃ is chosen from the group consisting of hydrogen and alkyl, R₄ is an amino group, and R₅ is hydrogen, or R₁ or R₂ together form a fused carbocyclic ring, and/or the amino group forming R⁴ completes with at least one of R⁴ and R⁶ a fused ring. The alkyl moieties in each instance contain from 1 to 5 carbon atoms, preferably 1 to 3 carbon atoms. The aryl moieties are preferably phenyl groups. The fused carbocyclic rings are preferably five, six or seven membered rings. The heterocyclic aromatic groups contain 5 or 6 membered heterocyclic rings containing carbon atoms and one or two heteroatoms chosen from the group consisting of oxygen, sulfur, and nitrogen. The amino group can be a primary, secondary, or tertiary amino group. When the amino nitrogen completes a fused ring with an adjacent substituent, the ring is preferably a five or six membered ring. For example, R⁴ can take the form of a pyran ring when the nitrogen atom forms a single ring with one adjacent substituent (R³ or R⁵) or a julolidine ring (including the fused benzo ring of the coumarin) when the nitrogen atom forms rings with both adjacent substituents R₃ and R₅.

The following are illustrative fluorescent coumarin dyes known to be useful as laser dyes: FD-1 7-Diethylamino-4-methylcoumarin, FD-2 4,6-Dimethyl-7-ethylaminocoumarin, FD-3 4-Methylumbelliferone, FD-4 3-(2′-Benzothiazolyl)-7-diethylaminocoumarin, PD-5 3-(2′-Benzimidazolyl)-7-N,N-diethylaminocoumarin, FD-6 7-Amino-3-phenylcoumarin, FD-7 3-(2′-N-Methylbenzimidazolyl)-7-N,N-diethylaminocoumarin, FD-8 7-Diethylamino-4-trifluoromethylcoumarin, FD-9 2,3,5,6-1H,4H-Tetrahydro-8-methylquinolazino[9,9a,1-gh]coumarin, FD-10 Cyclopenta[c]julolindino[9,10-3]-11H-pyran-1-one, FD-11 7-Amino-4-methylcoumarin, FD-12 7-Dimethylaminocyclopenta[c]coumarin, FD-13 7-Amino-4-trifluoromethylcoumarin, FD-14 7-Dimethylamino-4-trifluoromethylcoumarin, FD-15 1,2,4,5,3H,6H,10H-Tetrahydro-8-trifluoromethyl[1]benzopyrano[9,9a,1-gh]quinolizin-10-one, FD-16 4-Methyl-7-(sulfomethylamino)coumarin sodium salt, FD-17 7-Ethylamino-6-methyl-4-trifluoromethylcoumarin, FD-18 7-Dimethylamino-4-methylcoumarin, FD 19 1,2,4,5,3H,6H,10H-Tetrahydro-carbethoxy[1]benzopyrano[9,9a,1-gh]quinolizino-10-one, FD-20 9-Acetyl-1,2,4,5,3H,6H,10H-tetrahydro[1]benzopyrano[9,9a,1-gh]quinolizino-10-one, FD-21 9-Cyano-1,2,4,5,3H,6H,10H-tetrahydro[1]benzopyrano[9,9a,1-gh]quinolizino-10-one, FD22 9-(t-Butoxycarbonyl)-1,2,4,5,3H,6H,10H-tetrahydro[1]benzopyrano[9,9a,1-gh]quinolino-10-one, FD-23 4-Methylpiperidino[3,2-g]coumarin, FD-24 4-Trifluoromethylpiperidino[3,2-g]coumarin, FD-25 9-Carboxy-1,2,4,5,3H,6H,10H-tetrahydro[1]benzopyrano[9,9a,1-gh]quinolizino-10-one, FD-26 N-Ethyl-4-trifluoromethylpiperidino[3,2-g].

Other dopants include salts of bis benzene sulphonic acid such as

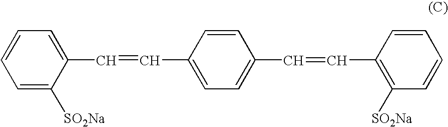

and perylene and perylene derivatives and dopants. Other dopants are dyes such as the fluorescent 4-dicyanomethylene-4H-pyrans and 4-dicyanomethylene-4H-thiopyrans, e.g. the fluorescent dicyanomethylenepyran and thiopyran dyes. Useful fluorescent dyes can also be selected from among known polymethine dyes, which include the cyanines, merocyanines, complex cyanines and merocyanines (i.e. tri-, tetra- and poly-nuclear cyanines and merocyanines), oxonols, hemioxonols, styryls, merostyryls, and streptocyanines. The cyanine dyes include, joined by a methine linkage, two basic heterocyclic nuclei, such as azolium or azinium nuclei for example, those derived from pyridinium, quinolinium, isoquinolinium, oxazolium, thiazolium, selenazolium, indazolium, pyrazolium, pyrrolium, indolium, 3H-indolium, imidazolium, oxadiazolium, thiadioxazolium, benzoxazolium, benzothiazolium, benzoselenazolium, benzotellurazolium, benzimidazolium, 3H- or 1H-benzoindolium, naphthoxazolium, naphthothiazolium, naphthoselenazolium, naphthotellurazolium, carbazolium, pyrrolopyridinium, phenanthrothiazolium, and acenaphthothiazolium quaternary salts. Other useful classes of fluorescent dyes are 4-oxo-4H-benz-[d,e]anthracenes and pyrylium, thiapyrylium, selenapyrylium, and telluropyrylium dyes.

In the case of aluminium quinolate, the compound below can serve as a red dopant:

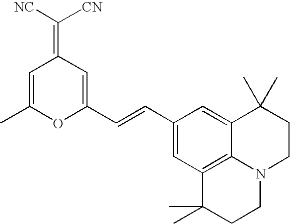

Also in the case of aluminium quinolate, the compounds below can serve as green dopants:

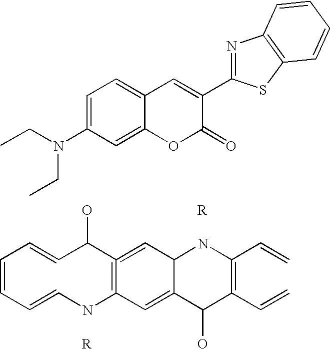

For the compound biphenyl aluminium bis quinolate (BAlQ₂), the compound perylene acts as a blue dopant.

Further blue-emitting materials are based on an organic host e.g a conjugated aromatic compound) and organic dopants e.g. the diarylamine anthracene compounds disclosed in WO 2006/090098 (Kathirgamanathan et al.). As example of a suitable host, there may be mentioned the compound

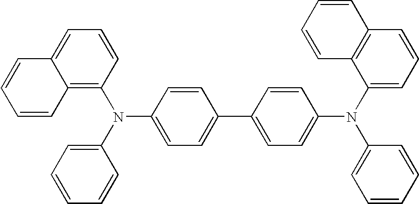

As dopants, there may be mentioned blue-emitting substituted anthracenes inter alia 9,10-bis(4-methylbenzyl)-anthracene, 9,10-bis-(2,4-dimethylbenzyl)-anthracene, 9,10-bis-(2,5-dimethylbenzyl)-anthracene, 1,4-bis-(2,3,5,6-tetramethylbenzyl)-anthracene, 9,10-bis-(4-methoxybenzyl)-anthracene, 9,10-bis(9H-fluoren-9-yl)-anthracene, 2,6-di-t-butylanthracene, 2,6-di-t-butyl-9,10-bis-(2,5-dimethylbenzyl)-anthracene, 2,6-di-t-butyl-9,10-bis-(naphthalene-1-ylmethyl)-anthracene.

For blue emitting OLEDs, TCTA may be used as host and it may be doped with the blue phosphorescent materials set out below, see WO 2005/080526 (Kathirgamanathan et al.)

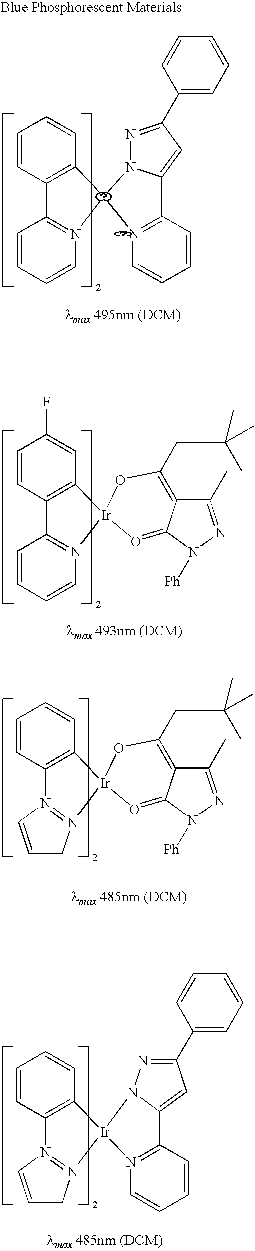

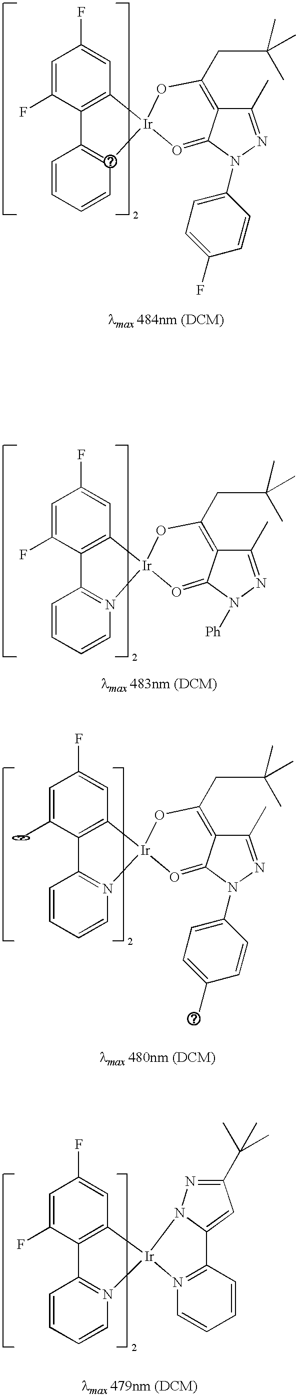

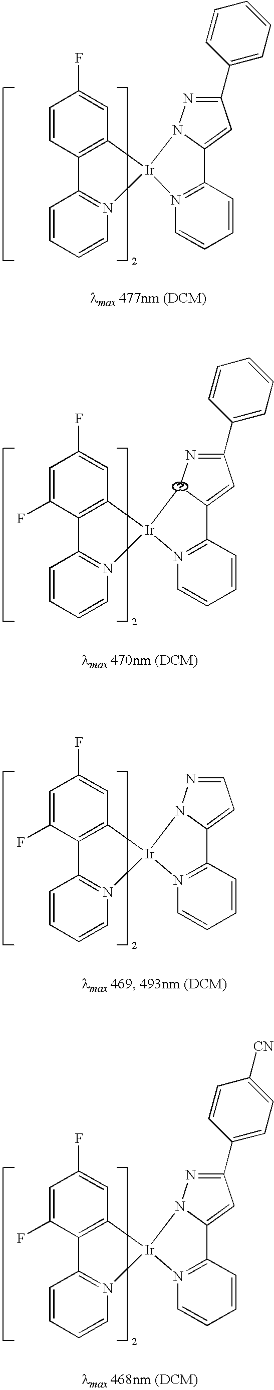

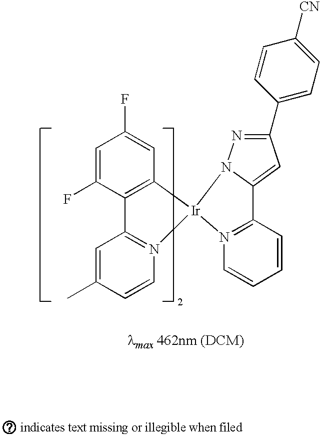

A variety of blue-emitting materials based e.g. on quinolates and substituted quinolates have been reported in the literature, although blue quinolate-based materials are rare. For example there may be mentioned the following patents, applications and publications, the contents of which are incorporated herein by reference:

U.S. Pat. No. 5,141,671 (Bryan, Kodak)—aluminum chelates containing a phenolato ligand and two 8-quinolinolato ligands

WO 00/32717 (Kathirgamanathan)—Lithium quinolate which is vacuum depositable, and other substituted quinolates of lithium where the substituents may be the same or different in the 2, 3, 4, 5, 6 and 7 positions and are selected from alky, alkoxy, aryl, aryloxy, sulphonic acids, esters, carboxylic acids, amino and amido groups or are aromatic, polycyclic or heterocyclic groups.

US 2006/0003089 (Kathirgamanathan)—Lithium quinolate made by reacting a lithium alkyl or alkoxide with 8-hydroxyquinoline in acetonitrile.

Misra, http://www.ursi.org/Proceedings/ProcGA05/pdf/D04.5(01720).pdf Blue organic electroluminescent material bis-(2-methyl 8-quinolinolato) (triphenyl siloxy)aluminum (III) which was vacuum depositable at 1×10⁻⁵ Torr.

Other classes of compound may also be used as blue emitters. For example WO 03/006573 (Kathirgamanathan et al) discloses metal pyrazolones of formula

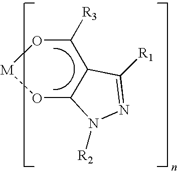

wherein, in the above formula:

M is lithium, sodium, potassium, rubidium, caesium, beryllium, magnesium, calcium, strontium, barium, copper, silver, gold, zinc, boron, aluminium, gallium, indium, germanium, tin, antimony, lead, manganese, iron, ruthenium, osmium, cobalt, rhodium, iridium, nickel, palladium, platinum, cadmium or chromium;

n is the valence of M; and

R₁, R₂ and R₃ can be the same or different, and are selected from hydrogen, a substituted or unsubstituted aliphatic group, a substituted or unsubstituted aromatic, heterocyclic or polycyclic ring structure, a fluorocarbon, a halogen or a nitrile group.

Particular compounds as disclosed in WO 03/006753 have the formula indicated below and have the properties set out in the table below:

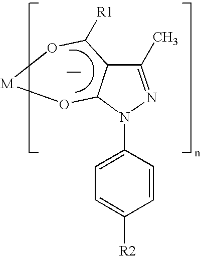

| | | Tg/ | | PL; | Colour |
|---|---|---|---|---|---|
| R₁ | R₂ | ° C. | Tm/° C. | λmax/nm | co-ord (x, y) |
| 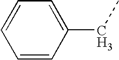 | H | — | 142 | 500 | 0.24, 0.34 |
| 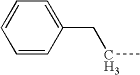 | H | — | 160 | 460 | 0.22, 0.25 |
| 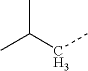 | H | — | 243-244 | 450 | 0.20, 0.21 |
| 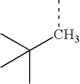 | H | 73 | 236 | 450 | 0.19, 0.21 |
| CH₃ | H | — | Semi-solid | — | 0.21, 0.26 |
| CH₂CH₃ | H | — | 182 | — | 0.20, 0.21 |
| 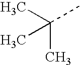 | H | — | 298 | — | 0.24, 0.31 |
| 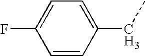 | H | — | | — | 0.23, 0.29 |
| 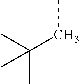 | F | — | 221 | 450 | 0.20, 0.21 |
| 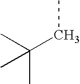 | CN | 113 | 259 | 450 | 0.20, 0.23 |
| 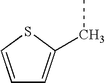 | H | — | — | 475 | 0.23, 0.28 |

As a further example, WO 2004/084325 (Kathirgamanathan et al) discloses boron complexes that are blue electroluminescent compounds and are of formula:

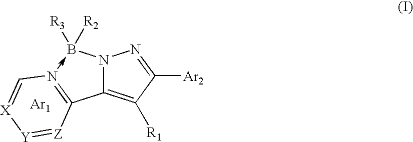

wherein:

Ar₁ represents unsubstituted or substituted monocyclic or polycyclic heteroaryl having a ring nitrogen atom for forming a coordination bond to boron as indicated and optionally one or more additional ring nitrogen atoms subject to the proviso that nitrogen atoms do not occur in adjacent positions, X and Z being carbon or nitrogen and Y being carbon or optionally nitrogen if neither of X and Z is nitrogen, said substituents if present being selected from substituted and unsubstituted hydrocarbyl, substituted and unsubstituted hydrocarbyloxy, fluorocarbon, halo, nitrile, amino alkylamino, dialkylamino or thiophenyl;

Ar₂ represents monocyclic or polycyclic aryl or heteroaryl optionally substituted with one or more substituents selected from substituted and unsubstituted hydrocarbyl, substituted and unsubstituted hydrocarbyloxy, fluorocarbon, halo, nitrile, amino, alkylamino, dialkylamino or thiophenyl;

R₁ represents hydrogen, substituted or unsubstituted hydrocarbyl, halohydrocarbyl or halo; and

R₂ and R₃ each independently represent alkyl, cycloalkyl, cycloalkylalkyl, haloalkyl, halo or monocyclic or polycyclic aryl, heteroaryl, aralkyl or heteroaralkyl optionally substituted with one or more of alkyl, cycloalkyl, cycloalkylalkyl, haloalkyl, aryl, aralkyl, alkoxy, aryloxy, halo, nitrile, amino, alkylamino or dialkylamino. Preferably substituents do not contain more than 6 carbon atoms. Representative compounds and their properties are set out below:

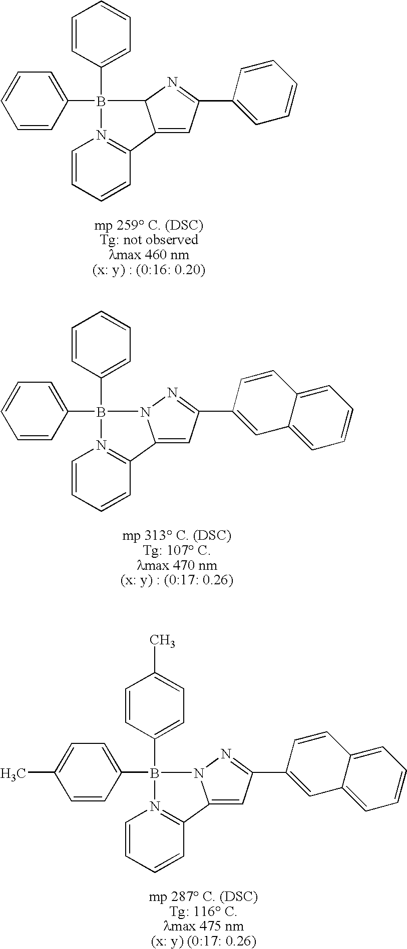

Ma et al., Chem. Comm. 1998, 2491-2492 disclose the preparation and crystal structure of a tetranuclear zinc(II) compound [Zn₄O(AID)₆] with 7-azaindolate as a bridging ligand. This compound is reported to have the desirable features for blue LED device fabrication that it can be easily prepared and is stable to air and moisture, and it displays an intense blue photoluminescence with a long lifetime and a high quantum yield at room temperature. Fabrication of inter alia a single-layer LED by vacuum deposition of this compound (<200° C., 2×10⁻⁶ Torr) onto a glass substrate coated with indium tin oxide to form a thin homogeneous film was reported

Blue phosphorescent iridium-based complexes are disclosed in WO 2005/080526 (Gamanathan et al) the contents of which are incorporated herein by reference.

For red-emitting OLEDs, the host may be CBP or TAZ and the dopant may be one of the phosphorescent materials set out below, see WO 2005/080526 (Kathirgamanathan et al.):

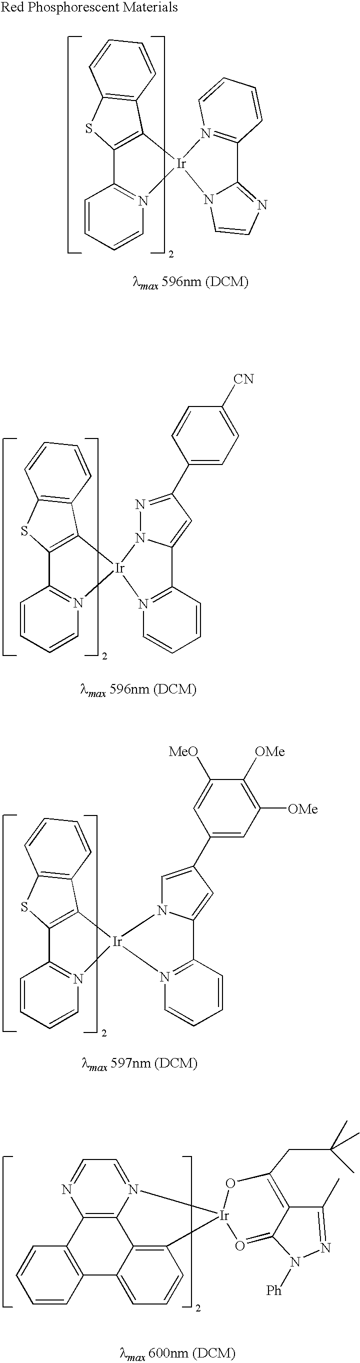

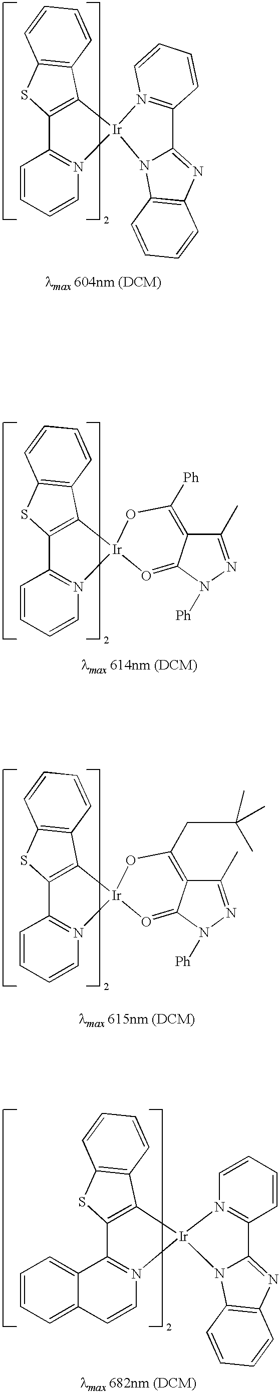

For green-emitting OLEDs, the host may also be CBP or TAZ and the dopant may be one of the phosphorescent materials set out below, see WO 2005/080526 (Kathirgamanathan et al.):

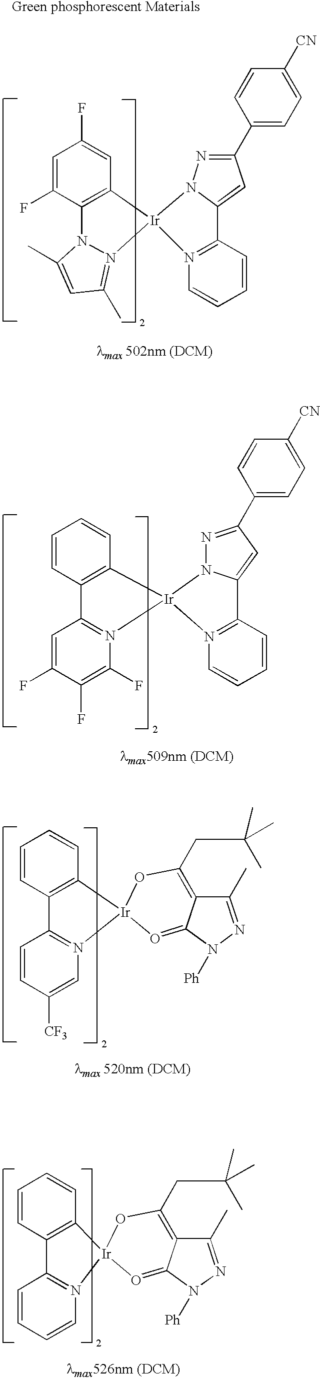

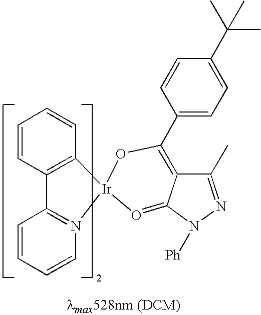

The electroluminescent material forming the electroluminescent layer can also be any known electroluminescent material, for example those disclosed in Patent Applications WO98/58037 PCT/GB98/01773, PCT/GB99/03619, PCT/GB99/04030, PCT/GB99/04024, PCT/GB99/04028 and PCT/GB00/00268 the contents of which are included by reference.

Preferred electroluminescent materials are electroluminescent compounds which can be used as the electroluminescent material in the present invention and are of general formula (Lα)ₙM where M is a rare earth, lanthanide or an actinide, Lα is an organic complex and n is the valence state of M.

Other organic electroluminescent compounds which can be used in the present invention are of formula

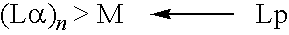

where Lα and Lp are organic ligands, M is a rare earth, transition metal, lanthanide or an actinide and n is the valence state of the metal M. The ligands Lα can be the same or different and there can be a plurality of ligands Lp which can be the same or different.

For example, (L₁)(L₂)(L₃)(L . . . )M(Lp) where M is a rare earth, transition metal, lanthanide or an actinide and (L₁)(L₂)(L₃)(L . . . ) are the same or different organic complexes and (Lp) is a neutral ligand. The total charge of the ligands (L₁)(L₂)(L₃)(L . . . ) is equal to the valence state of the metal M. Where there are 3 groups Lα which corresponds to the III valence state of M the complex has the formula (L₁)(L₂)(L₃)M(Lp) and the different groups (L₁)(L₂)(L₃) may be the same or different.

Lp can be monodentate, bidentate or polydentate and there can be one or more ligands Lp.

Preferably M is a metal ion having an unfilled inner shell and the preferred metals are selected from Sm(III), Eu(II), Eu(III), Tb(III), Dy(III), Yb(III), Lu(III), Gd(III), Gd(III) U(III), Tm(III), Ce(III), Pr(III), Nd(III), Pm(III), Dy(III), Ho(III), Er(III), Yb(III) and more preferably Eu(III), Th(III), Dy(III), Gd(III), Er(III), Yt(III).

Further organic electroluminescent compounds which can be used in the present invention are of general formula (Lα)ₙM₁M₂ where M₁ is the same as M above, M₂ is a non rare earth metal, Lα is as above and n is the combined valence state of M₁ and M₂. The complex can also comprise one or more neutral ligands Lp so the complex has the general formula (Lα)ₙM₁M₂(Lp), where Lp is as above. The metal M₂ can be any metal which is not a rare earth, transition metal, lanthanide or an actinide. Examples of metals which can be used include lithium, sodium, potassium, rubidium, caesium, beryllium, magnesium, calcium, strontium, barium, copper (I), copper (II), silver, gold, zinc, cadmium, boron, aluminium, gallium, indium, germanium, tin (II), tin (IV), antimony (II), antimony (IV), lead (II), lead (I) and metals of the first, second and third groups of transition metals in different valence states e.g. manganese, iron, ruthenium, osmium, cobalt, nickel, palladium(II), palladium(IV), platinum(II), platinum(IV), cadmium, chromium titanium, vanadium, zirconium, tantalum, molybdenum, rhodium, iridium, titanium, niobium, scandium, yttrium.

For example (L₁)(L₂)(L₃)(L . . . )M(Lp) where M is a rare earth, transition metal, lanthanide or an actinide and (L₁)(L₂)(L₃)(L . . . ) and (Lp) are the same or different organic complexes.

Further organometallic complexes which can be used in the present invention are binuclear, trinuclear and polynuclear organometallic complexes e.g. of formula (Lm)ₓM₁←M₂(Ln)_{y} e.g.

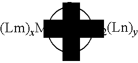

where L is a bridging ligand and where M₁ is a rare earth metal and M₂ is M₁ or a non rare earth metal, Lm and Ln are the same or different organic ligands Lα as defined above, x is the valence state of M₁ and y is the valence state of M₂. In these complexes there can be a metal to metal bond or there can be one or more bridging ligands between M₁ and M₂ and the group Lm and Ln can be the same or different By trinuclear is meant there are three rare earth metals joined by a metal to metal bond i.e. of formula

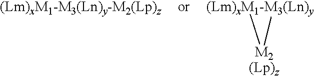

where M₁, M₂ and M₃ are the same or different rare earth metals and Lm, Ln and Lp are organic ligands Lα and x is the valence state of M₁, y is the valence state of M₂ and z is the valence state of M₃. Lp can be the same as Lm and Ln or different. The rare earth metals and the non rare earth metals can be joined together by a metal to metal bond and/or via an intermediate bridging atom, ligand or molecular group. For example the metals can be linked by bridging ligands, e.g.

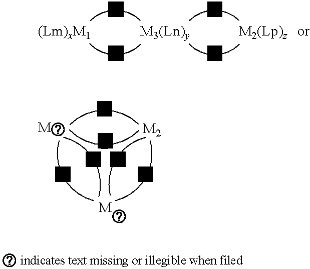

where L is a bridging ligand.

By ‘polynuclear’ is meant there are more than three metals joined by metal to metal bonds and/or via intermediate ligands

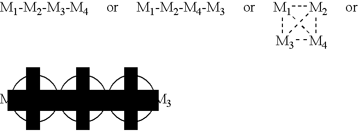

where M₁, M₂, M₃ and M₄ are rare earth metals and L is a bridging ligand.

Preferably Lα is selected from a diketones such as those of formulae

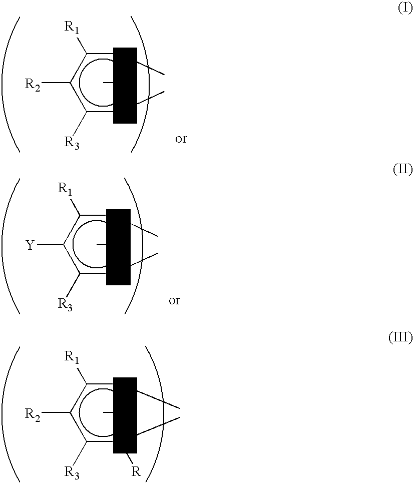

where R₁, R₂ and R₃ can be the same or different and are selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine or thiophenyl groups; R₁, R₂ and R₃ can also form substituted and unsubstituted fused aromatic, heterocyclic and polycyclic ring structures and can be copolymerisable with a monomer e.g. styrene. X is Se, S or O, Y can be hydrogen, substituted or unsubstituted hydrocarbyl groups, such as substituted and unsubstituted aromatic, heterocyclic and polycyclic ring structures, fluorine, fluorocarbons such as trifluoryl methyl groups, halogens such as fluorine or thiophenyl groups or nitrile.

The beta diketones can be polymer substituted beta diketones and in the polymer, oligomer or dendrimer substituted β diketone the substituents group can be directly linked to the diketone or can be linked through one or more —CH₂ groups i.e.

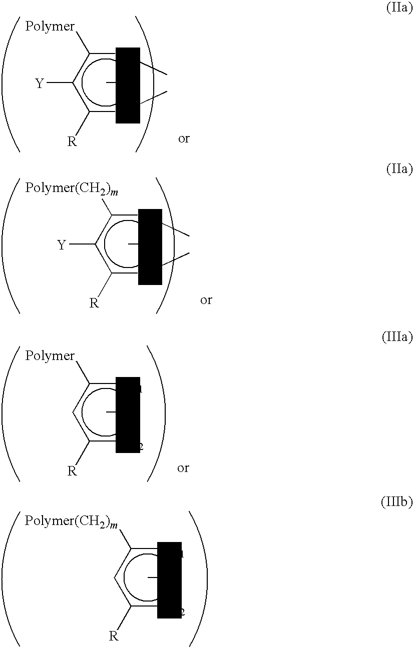

or through phenyl groups e.g.

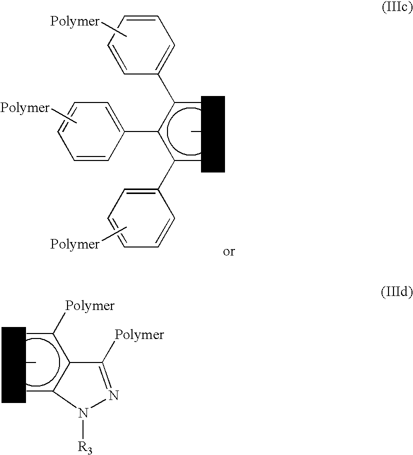

where “polymer” can be a polymer, an oligomer or a dendrimer, (there can be one or two substituted phenyl groups as well as three as shown in (IIIc)) and where R is selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine or thiophenyl groups.

Examples of R₁ and/or R₂ and/or R₃ include aliphatic, aromatic and heterocyclic alkoxy, aryloxy and carboxy groups, substituted and substituted phenyl, fluorophenyl, biphenyl, phenanthrene, anthracene, naphthyl and fluorene groups alkyl groups such as t-butyl, heterocyclic groups such as carbazole.

Some of the different groups Lα may also be the same or different charged groups such as carboxylate groups so that the group L₁ can be as defined above and the groups L₂, L₃ . . . can be charged groups such as

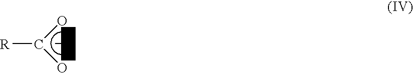

where R is R₁ as defined above or the groups L₁, L₂ can be as defined above and L₃ . . . etc. are other charged groups.
R₁, R₂ and R₃ can also be

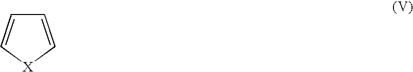

where X is O, S, Se or NH.

A preferred moiety R₁ is trifluoromethyl CF₃ and examples of such diketones are, banzoyltrifluoroacetone, p-chlorobenzoyltrifluoroacetone, p-bromotrifluoroacetone, p-phenyltrifluoroacetone, 1-naphthoyltrifluoroacetone, 2-naphthoyltrifluoroacetone, 2-phenathoyltrifluoroacetone, 3-phenanthoyltrifluoroacetone, 9-anthroyltrifluoroacetonetrifluoroacetone, cinnamoyltrifluoroacetone, and 2-thenoyltrifluoroacetone.

The different groups Lα may be the same or different ligands of formulae

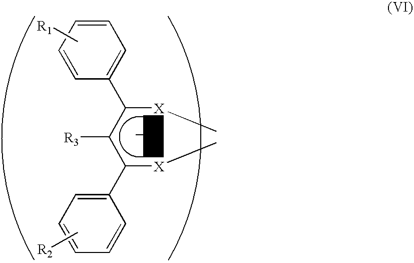

where X is O, S, or Se and R₁ R₂ and R₃ are as above.

The different groups Lα may be the same or different quinolate derivatives such as

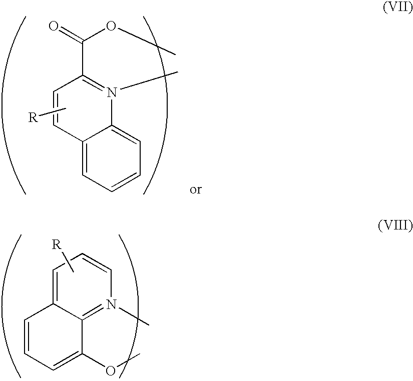

where R is hydrocarbyl, aliphatic, aromatic or heterocyclic carboxy, aryloxy, hydroxy or alkoxy e.g. the 8 hydroxy quinolate derivatives or

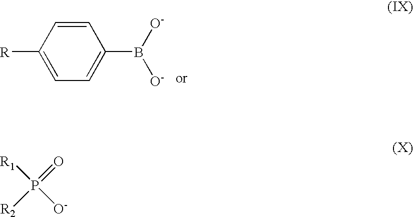

where R, R₁, and R₂ are as above or are H or F e.g. R₁ and R₂ are alkyl or alkoxy groups

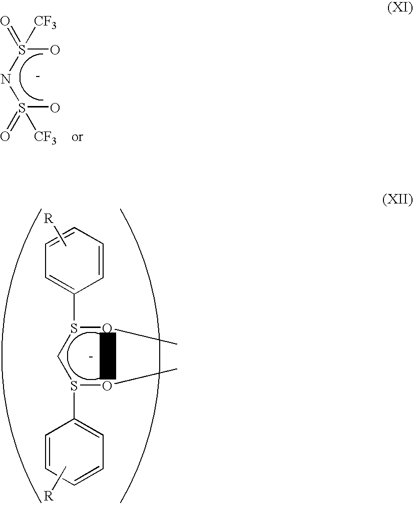

As stated above the different groups Lα may also be the same or different carboxylate groups e.g.

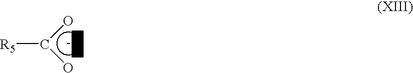

where R₅ is a substituted or unsubstituted aromatic, polycyclic or heterocyclic ring a polypyridyl group, R₅ can also be a 2-ethyl hexyl group so Lₙ is 2-ethylhexanoate or R₅ can be a chair structure so that Lₙ is 2-acetyl cyclohexanoate or Lα can be

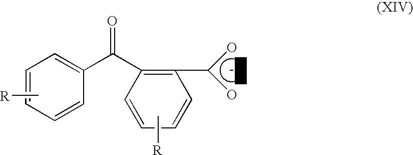

where R is as above e.g. alkyl, allenyl, amino or a fused ring such as a cyclic or polycyclic ring.

The different groups Lα may also be

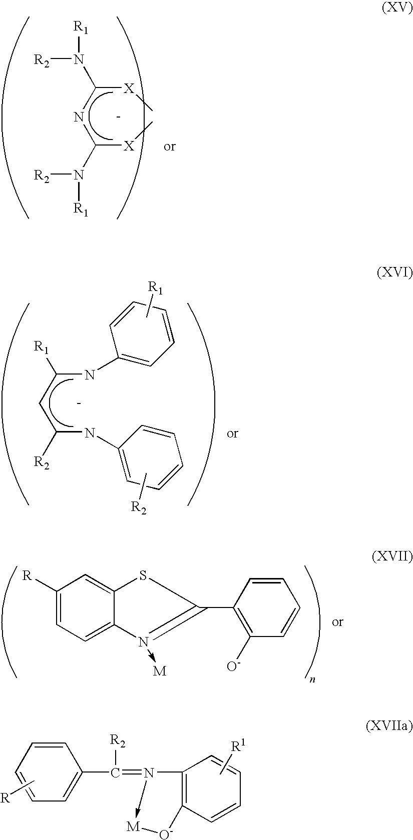

where R, R₁ and R₂ are as above.

The groups Lₚ can be selected from

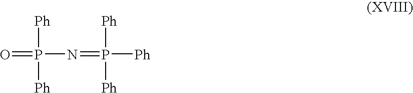

where each Ph which can be the same or different and can be a phenyl (OPNP) or a substituted phenyl group, other substituted or unsubstituted aromatic group, a substituted or unsubstituted heterocyclic or polycyclic group, a substituted or unsubstituted fused aromatic group such as a naphthyl, anthracene, phenanthrene or pyrene group. The substituents can be for example an alkyl, aralkyl alkoxy, aromatic, heterocyclic, polycyclic group, halogen such as fluorine, cyano, amino, substituted amino etc. Examples are compounds 1, 2a and 2b in the Scheme below where R, R₁, R₂, R₃ and R₄ can be the same or different and are selected from hydrogen, hydrocarbyl groups, substituted and unsubstituted aromatic, heterocyclic and polycyclic ring structures, fluorocarbons such as trifluoryl methyl groups, halogens such as fluorine or thiophenyl groups; R, R₁, R₂, R₃ and R₄ can also form substituted and unsubstituted fused aromatic, heterocyclic and polycyclic ring structures and can be copolymerisable with a monomer e.g. styrene. R, R₁, R₂, R₃ and R₄ can also be unsaturated alkylene groups such as vinyl groups or groups

—C—CH₂═CH₂—R

where R is as above.

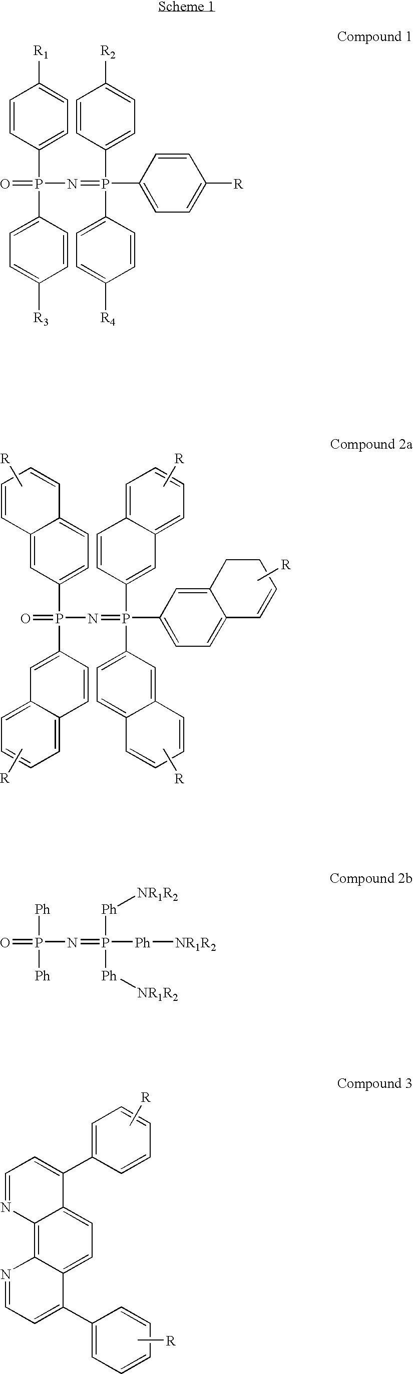

Lₚ can also be compounds of formulae

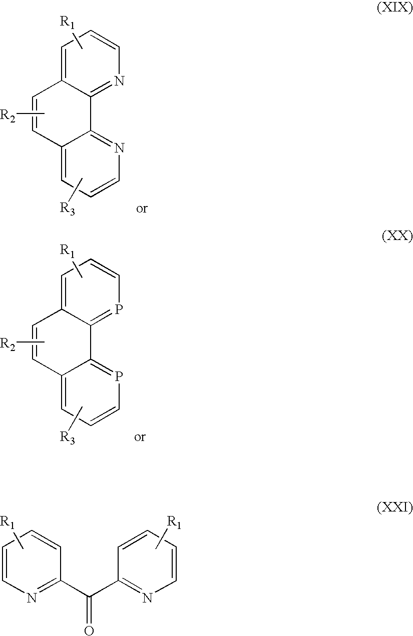

where R₁, R₂ and R₃ are as referred to above, for example bathophen shown as Compound 3 above in which R is as above or

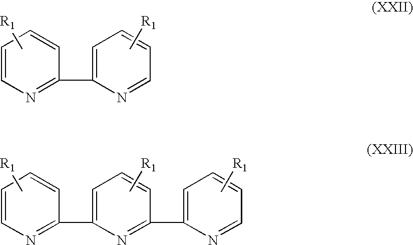

where R₁, R₂ and R₃ are as referred to above.
Lₚ can also be

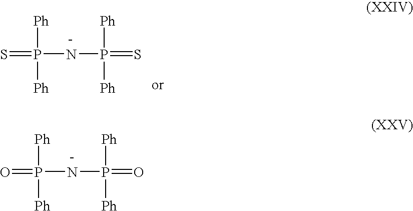

where Ph is as above.

Other examples of Lₚ chelates are as shown in Scheme 2

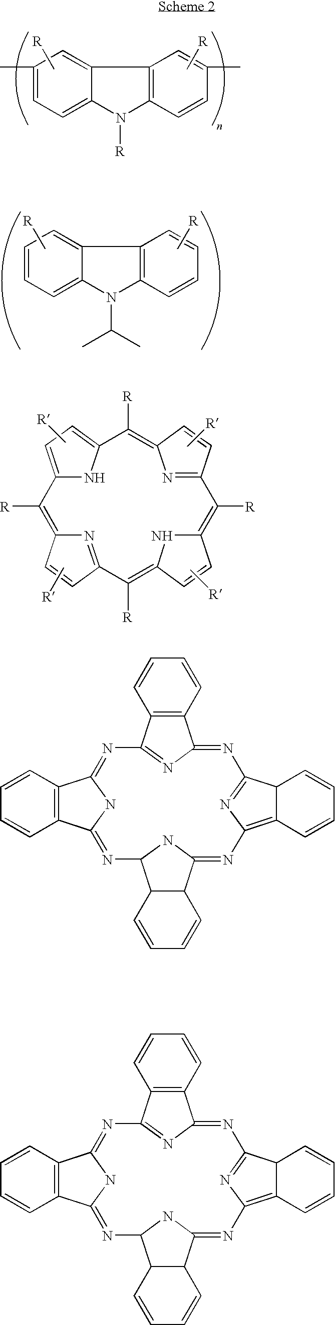

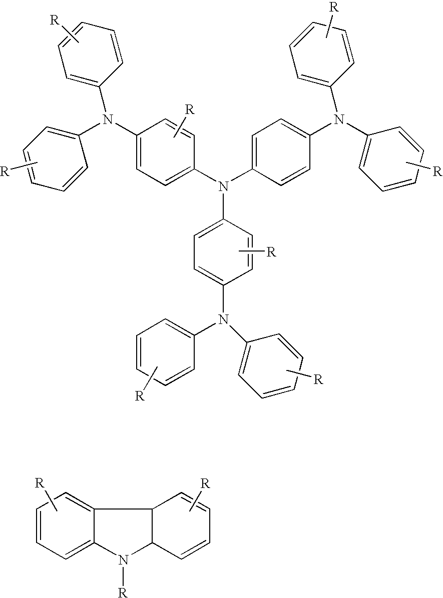

and fluorene and fluorene derivatives e.g. as shown in Scheme 3

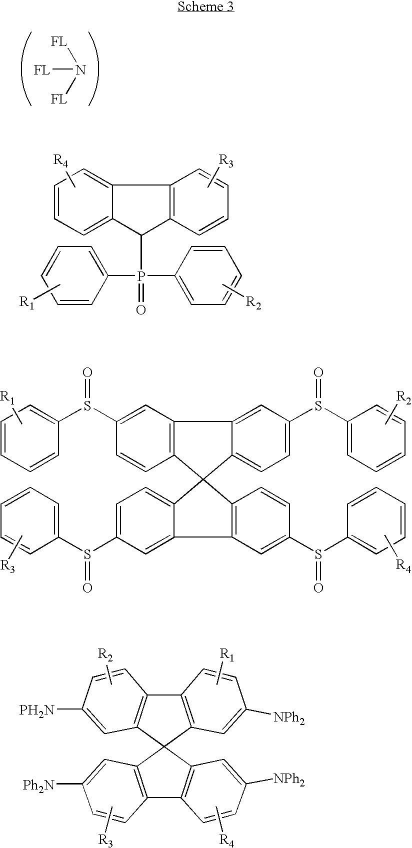

and compounds of formulae as shown in Schemes 4-6.

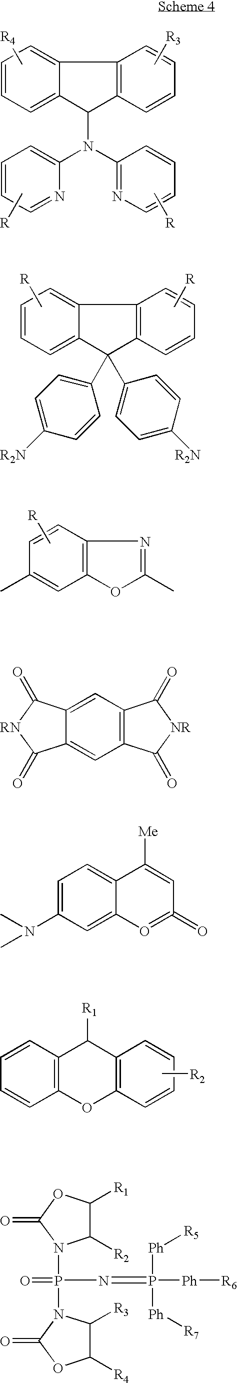

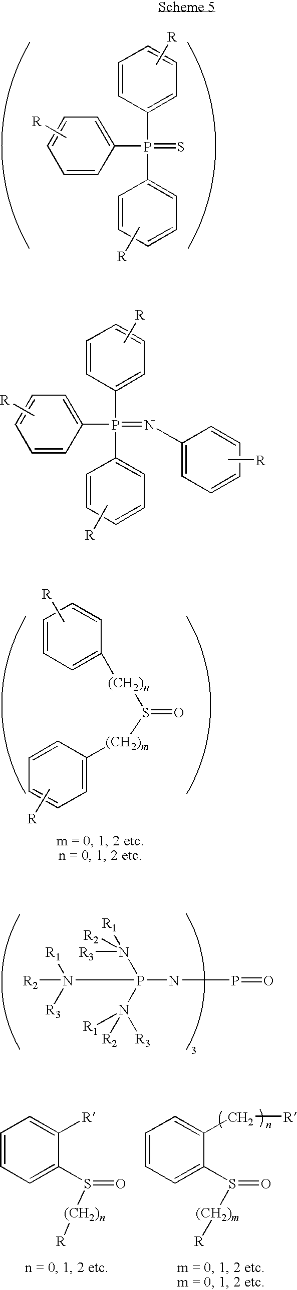

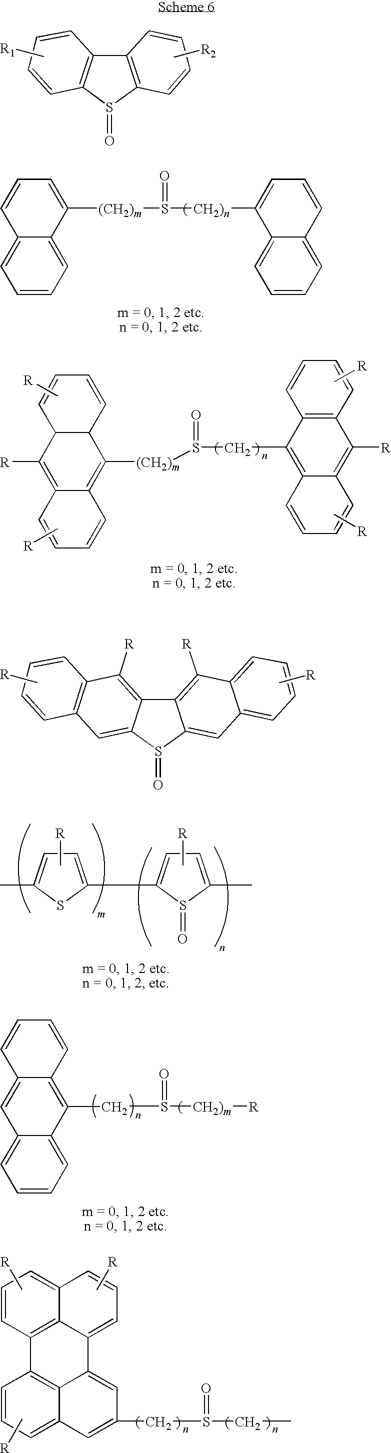

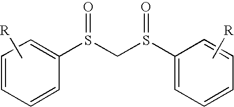

Specific examples of Lα and Lp are tripyridyl and TMHD, and TMHD complexes, α, α′, α″ tripyridyl, crown ethers, cyclans, cryptans phthalocyanans, porphoryins ethylene diamine tetramine (EDTA), DCTA, DTPA and TTHA, where TMHD is 2,2,6,6-tetramethyl-3,5-heptanedionato and OPNP is diphenylphosphonimide triphenyl phosphorane. The formulae of the polyamines are shown in Scheme 7.

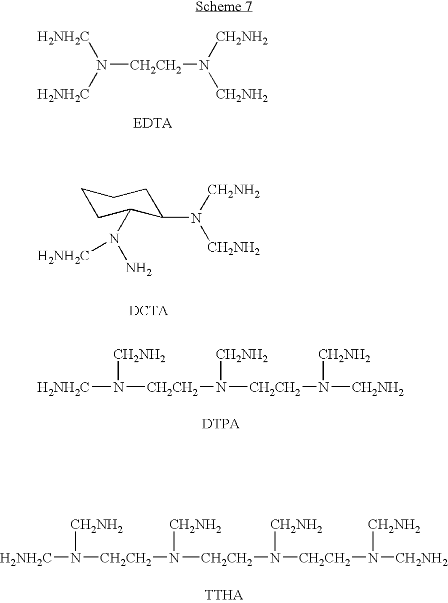

Other organic electroluminescent materials which can be used include metal quinolates such as lithium quinolate, and non rare earth metal complexes such as aluminium, magnesium, zinc and scandium complexes such as complexes of p-diketones e.g. Tris-(1,3-diphenyl-1-3-propanedione) (DBM) and suitable metal complexes are Al(DBM)₃, Zn(DBM)₂ and Mg(DBM)₂, Sc(DBM)₃ etc.

Other organic electroluminescent materials which can be used include the metal complexes of formula

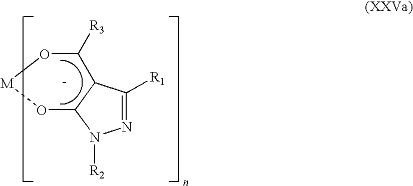

where M is a metal other than a rare earth, a transition metal, a lanthanide or an actinide; n is the valency of M; R₁, R₂ and R₃ which may be the same or different are selected from hydrogen, hydrocarbyl groups, substituted and unsubstituted aliphatic groups substituted and unsubstituted aromatic, heterocyclic and polycyclic ring structures, fluorocarbons such as trifluoryl methyl groups, halogens such as fluorine or thiophenyl groups or nitrile; R₁, and R₃ can also form ring structures and R₁, R₂ and R₃ can be copolymerisable with a monomer e.g. styrene. Preferably M is aluminium and R₃ is a phenyl or substituted phenyl group.

Other organic electroluminescent materials which can be used include electroluminescent diiridium compounds of formula

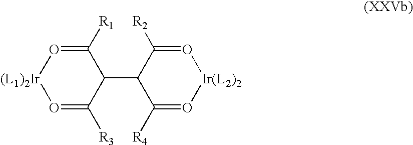

where R₁, R₂, R₃ and R₄ can be the same or different and are selected from hydrogen, and substituted and unsubstituted hydrocarbyl groups; preferably R₁, R₂, R₃ and R₄ are selected from substituted and unsubstituted aliphatic groups, substituted and unsubstituted aromatic, heterocyclic and polycyclic ring structures, fluorocarbons such as trifluoryl methyl groups, halogens such as fluorine or thiophenyl groups; R₁, R₂ and R₃ can also form substituted and unsubstituted fused aromatic, heterocyclic and polycyclic ring structures and can be copolymerisable with a monomer and L₁ and L₂ are the same or different organic ligands and more preferably L₁ and L₂ are selected from phenyl pyridine and substituted phenylpryidines.

Other indium complexes which can be used include electroluminescent complexes of formula

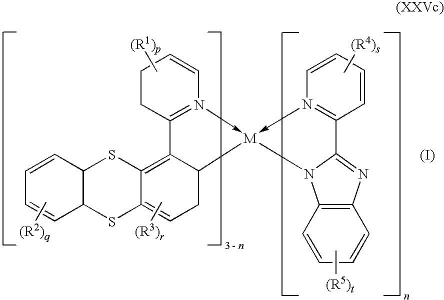

wherein M is ruthenium, rhodium, palladium, osmium, iridium or platinum; n is 1 or 2; R¹, R⁴ and R⁵ can be the same or different and are selected from substituted and unsubstituted hydrocarbyl groups; substituted and unsubstituted monocyclic and polycyclic heterocyclic groups; substituted and unsubstituted hydrocarbyloxy or carboxy groups; fluorocarbyl groups; halogen; nitrile; amino; alkylamino; dialkylamino; arylamino; diarylamino; and thiophenyl; p, s and t independently are 0, 1, 2 or 3; subject to the proviso that where any of p, s and t is 2 or 3 only one of them can be other than saturated hydrocarbyl or halogen; R² and R³ can be the same or different and are selected from; substituted and unsubstituted hydrocarbyl groups; halogen; q and r independently are 0, 1 or 2 and complexes of formula

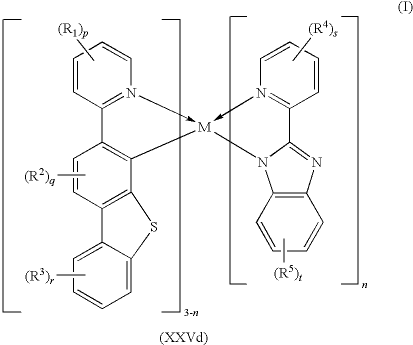

wherein M is ruthenium, rhodium, palladium, osmium, iridium or platinum; n is 1 or 2; R¹-R⁵ which may be the same or different are selected from substituted and unsubstituted hydrocarbyl groups; substituted and unsubstituted monocyclic and polycyclic heterocyclic groups; substituted and unsubstituted hydrocarbyloxy or carboxy groups; fluorocarbyl groups; halogen; nitrile; nitro; amino; alkylamino; dialkylamino; arylamino; diarylamino; N-alkylamido, N-arylamido, sulfonyl and thiophenyl; and R² and R³ can additionally be alkylsilyl or arylsilyl; p, s and t independently are 0, 1, 2 or 3; subject to the proviso that where any of p, s and t is 2 or 3 only one of them can be other than saturated hydrocarbyl or halogen; q and r independently are 0, 1 or 2, subject to the proviso that when q or r is 2, only one of them can be other than saturated hydrocarbyl or halogen, compounds of formula

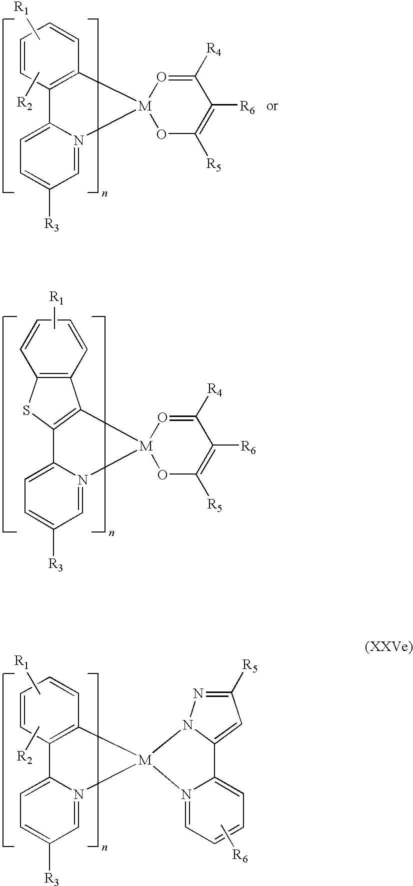

where R₁, R₂, R₃, R₄, R₅ and R₆ can be the same or different and are selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine or thiophenyl groups; R₁, R₂ and R₃ can also form substituted and unsubstituted fused aromatic, heterocyclic and polycyclic ring structures and can be copolymerisable with a monomer, e.g. styrene, and where R₄, and R₅ can be the same or different and are selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine or thiophenyl groups; R₁, R₂ and R₃ can also form substituted and unsubstituted fused aromatic, heterocyclic and polycyclic ring structures and can be copolymerisable with a monomer, M is ruthenium, rhodium, palladium, osmium, iridium or platinum and n+2 is the valency of M, compounds of formula

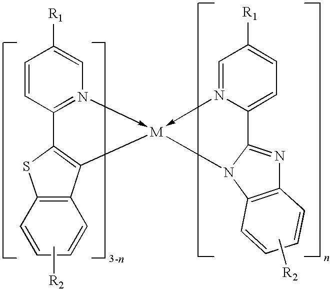

where R₁, and R₂ can be the same or different and are selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine or thiophenyl groups; substituted and unsubstituted hydrocarbyl groups such as substituted and unsubstituted aliphatic groups, substituted and unsubstituted aliphatic groups, M is ruthenium, rhodium, palladium, osmium, iridium or platinum and n is 1 or 2 and electroluminescent compounds of formula

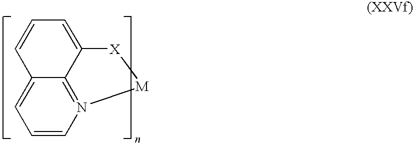

where M is a metal; X is O or S, n is the valency of M; R and R₁ which can be the same or different are selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine; thiophenyl groups; cyano group; substituted and unsubstituted hydrocarbyl groups such as substituted and unsubstituted aliphatic groups, substituted and unsubstituted aliphatic groups. M can be, for example, titanium vanadium, niobium or tantalum, and compounds of formula MOqₓ where q is a quinolate or thioxinate as in XXXVf and x+2 is the valency of M.

In another electroluminescent structure the electroluminescent layer is formed of layers of two electroluminescent organic complexes in which the band gap of the second electroluminescent metal complex or organo metallic complex such as a gadolinium or cerium complex is larger than the band gap of the first electroluminescent metal complex or organo metallic complex such as a europium or terbium complex.

Other electroluminescent compounds which can be used are of formula

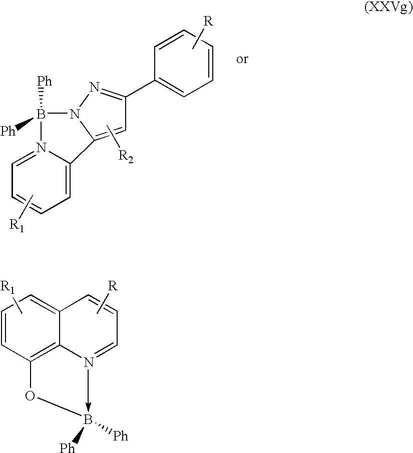

where Ph is an unsubstituted or substituted phenyl group where the substituents can be the same or different and are selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine or thiophenyl groups; R, R₁ and R₂ can be hydrogen or substituted or unsubstituted hydrocarbyl groups, such as substituted and unsubstituted aromatic, heterocyclic and polycyclic ring structures, fluorine, fluorocarbons such as trifluoryl methyl groups, halogens such as fluorine or thiophenyl groups or nitrile.

Examples of R and/or R₁ and/or R₂ and/or R₃ include aliphatic, aromatic and heterocyclic alkoxy, aryloxy and carboxy groups, substituted and substituted phenyl, fluorophenyl, biphenyl, phenanthrene, anthracene, naphthyl and fluorene groups alkyl groups such as t-butyl, heterocyclic groups such as carbazole.

Further electroluminescent materials which can be used include metal quinolates such as aluminium quinolate, lithium quinolate, zirconium quinolate etc.

Yet further electroluminescent materials include host materials e.g. metal quinolates (e.g. aluminium quinolate or zirconium quinolate) doped with fluorescent materials or dyes as disclosed in patent application WO 2004/058913. Preferably the electroluminescent compound is doped with a minor amount of a fluorescent material as a dopant, preferably in an amount of 5 to 15% by weight of the doped mixture. As discussed in U.S. Pat. No. 4,769,292, the contents of which are included by reference, the presence of the fluorescent material permits a choice from amongst a wide latitude of wavelengths of light emission.

In particular, as disclosed in U.S. Pat. No. 4,769,292 by blending with the organo metallic complex, a minor amount of a fluorescent material capable of emitting light in response to hole-electron recombination, the hue of the light emitted from the luminescent zone, can be modified. In theory, in the present application if a host material and a fluorescent material could be found for blending which have exactly the same affinity for hole-electron recombination, each material should emit light upon injection of holes and electrons in the luminescent zone. The perceived hue of light emission would be the visual integration of both emissions. However since imposing such a balance of host material and fluorescent materials is highly limiting, it is preferred to choose the fluorescent material so that it provides the favoured sites for light emission. When only a small proportion of fluorescent material providing favoured sites for light emission is present, peak intensity wavelength emissions typical of the host material can be entirely eliminated in favour of a new peak intensity wavelength emission attributable to the fluorescent material. While the minimum proportion of fluorescent material sufficient to achieve this effect varies, in no instance is it necessary to employ more than about 10 mole percent fluorescent material, based of host material and seldom is it necessary to employ more than 1 mole percent of the fluorescent material. On the other hand, limiting the fluorescent material present to extremely small amounts, typically less than about 10⁻³ mole percent, based on the host material, can result in retaining emission at wavelengths characteristic of the host material. Thus, by choosing the proportion of a fluorescent material capable of providing favoured sites for light emission, either a full or partial shifting of emission wavelengths can be realized. This allows the spectral emissions of the EL devices to be selected and balanced to suit the application to be served.

Choosing fluorescent materials capable of providing favoured sites for light emission, necessarily involves relating the properties of the fluorescent material to those of the host material. The host can be viewed as a collector for injected holes and electrons with the fluorescent material providing the molecular sites for light emission. One important relationship for choosing a fluorescent material capable of modifying the hue of light emission when present in the host is a comparison of the reduction potentials of the two materials. The fluorescent materials demonstrated to shift the wavelength of light emission have exhibited a less negative reduction potential than that of the host. Reduction potentials, measured in electron volts, have been widely reported in the literature along with varied techniques for their measurement. Since it is a comparison of reduction potentials rather than their absolute values which is desired, it is apparent that any accepted technique for reduction potential measurement can be employed, provided both the fluorescent and host reduction potentials are similarly measured A preferred oxidation and reduction potential measurement techniques is reported by R. J. Cox, Photographic Sensitivity, Academic Press, 1973, Chapter 15.

A second important relationship for choosing a fluorescent material capable of modifying the hue of light emission when present in the host is a comparison of the bandgap potentials of the two materials. The fluorescent materials demonstrated to shift the wavelength of light emission have exhibited a lower bandgap potential than that of the host. The bandgap potential of a molecule is taken as the potential difference in electron volts (eV) separating its ground state and first singlet state. Bandgap potentials and techniques for their measurement have been widely reported in the literature. The bandgap potentials herein reported are those measured in electron volts (eV) at an absorption wavelength which is bathochromic to the absorption peak and of a magnitude one tenth that of the magnitude of the absorption peak. Since it is a comparison of bandgap potentials rather than their absolute values which is desired, it is apparent that any accepted technique for bandgap measurement can be employed, provided both the fluorescent and zirconium 2-methyl quinolate bandgaps are similarly measured. One illustrative measurement technique is disclosed by F. Gutman and L. E. Lyons, Organic Semiconductors, Wiley, 1967, Chapter 5.

With aluminium or zirconium quinolate, which are themselves capable of emitting light in the absence of the fluorescent material, it has been observed that suppression of light emission at the wavelengths of emission characteristics of the quinolate alone and enhancement of emission at wavelengths characteristic of the fluorescent material occurs when spectral coupling of the quinolate and fluorescent material is achieved. By “spectral coupling” it is meant that an overlap exists between the wavelengths of emission characteristic of the quinolate alone and the wavelengths of light absorption of the fluorescent material in the absence of the quinolate. Optimal spectral coupling occurs when the emission wavelength of the quinolate is 125 nm of the maximum absorption of the fluorescent material alone. In practice advantageous spectral coupling can occur with peak emission and absorption wavelengths differing by up to 100 nm or more, depending on the width of the peaks and their hypsochromic and bathochromic slopes. Where less than optimum spectral coupling between the zirconium 2-methyl quinolate and fluorescent materials is contemplated, a bathochromic as compared to a hypsochromic displacement of the fluorescent material produces more efficient results.

Useful fluorescent materials are those capable of being blended with the quinolate or other host and fabricated into thin films satisfying the thickness ranges described above forming the luminescent zones of the EL devices of this invention. While crystalline organometallic complexes do not lend themselves to thin film formation, the limited amounts of fluorescent materials present in the host permits the use of fluorescent materials which are alone incapable of thin film formation. Preferred fluorescent materials are those which form a common phase with the host. Fluorescent dyes constitute a preferred class of fluorescent materials, since dyes lend themselves to molecular level distribution in the host. Although any convenient technique for dispersing the fluorescent dyes in the host can be undertaken, preferred fluorescent dyes are those which can be vacuum vapour deposited along with the host materials.

Assuming other criteria, noted above, are satisfied, fluorescent laser dyes are recognized to be particularly useful fluorescent materials for use in the organic EL devices of this invention. Dopants which can be used include diphenylacridine, coumarins, perylene and their derivatives. Useful fluorescent dopants are disclosed in U.S. Pat. No. 4,769,292. One class of preferred dopants is coumarins such as those of formula

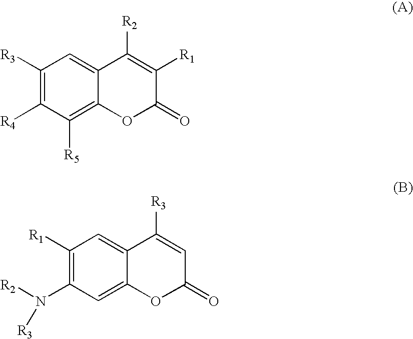

where R₁ is chosen from the group consisting of hydrogen, carboxy, alkanoyl, alkoxycarbonyl, cyano, aryl, and a heterocylic aromatic group, R₂ is chosen from the group consisting of hydrogen, alkyl, haloalkyl, carboxy, alkanoyl, and alkoxycarbonyl, R₃ is chosen from the group consisting of hydrogen and alkyl, R⁴ is an amino group, and R⁵ is hydrogen, or R₁ or R₂ together form a fused carbocyclic ring, and/or the amino group forming R⁴ completes with at least one of R⁴ and R⁶ a fused ring. The alkyl moieties in each instance contain from 1 to 5 carbon atoms, preferably 1 to 3 carbon atoms. The aryl moieties are preferably phenyl groups. The fused carbocyclic rings are preferably five, six or seven membered rings. The heterocyclic aromatic groups contain 5 or 6 membered heterocyclic rings containing carbon atoms and one or two heteroatoms chosen from the group consisting of oxygen, sulfur, and nitrogen. The amino group can be a primary, secondary, or tertiary amino group. When the amino nitrogen completes a fused ring with an adjacent substituent, the ring is preferably a five or six membered ring. For example, R⁴ can take the form of a pyran ring when the nitrogen atom forms a single ring with one adjacent substituent (R³ or R⁵) or a julolidine ring (including the fused benzo ring of the coumarin) when the nitrogen atom forms rings with both adjacent substituents R₃ and R₅.

The following are illustrative fluorescent coumarin dyes known to be useful as laser dyes: FD-1 7-Diethylamino-4-methylcoumarin, FD-2 4,6-Dimethyl-7-ethylaminocoumarin, FD-3 4-Methylumbelliferone, FD-4 3-(2′-Benzothiazolyl)-7-diethylaminocoumarin, F)-5 3-(2′-Benzimidazolyl)-7-N,N-diethylaminocoumarin, FD-6 7-Amino-3-phenylcoumarin, FD-7 3-(2′-N-Methylbenzimidazolyl)-7-N,N-diethylaminocoumarin, FD-8 7-Diethylamino-4-trifluoromethylcoumarin, FD-9 2,3,5,6-1H,4H-Tetrahydro-8-methylquinolazino[9,9a,1-gh]coumarin, FD-10 Cyclopenta[c]julolindino[9,10-3]-11H-pyran-11-one, FD-11 7-Amino-4-methylcoumarin, FD-12 7-Dimethylaminocyclopenta[c]coumarin, FD-13 7-Amino-4-trifluoromethylcoumarin, FD-14 7-Dimethylamino-4-trifluoromethylcoumarin, FD-15 1,2,4,5,3H,6H,10H-Tetrahydro-8-trifluoromethyl[1]benzopyrano[9,9a,1-gh]quinolizin-10-one, FD-16 4-Methyl-7-(sulfomethylamino)coumarin sodium salt, FD-17 7-Ethylamino-6-methyl-4-trifluoromethylcoumarin, FD-18 7-Dimethylamino-4-methylcoumarin, FD-19 1,2,4,5,3H,6H,10H-Tetrahydro-carbethoxy[1]benzopyrano[9,9a,1-gh]quinolizino-10-one, FD-20 9-Acetyl-1,2,4,5,3H,6H,10H-tetrahydro[1]benzopyrano[9,9a,1-gh]quinolizino-10-one, FD-21 9-Cyano-1,2,4,5,3H,6H,10H-tetrahydro[1]benzopyrano[9,9a,1-gh]quinolizino-10-one, FD22 9-(t-Butoxycarbonyl)-1,2,4,5,3H,6H,10H-tetrahydro[1]benzopyrano[9,9a,1-gh]quinolizino-10-one, FD-23 4-Methylpiperidino[3,2-g]coumarin, FD-24 4-Trifluoromethylpiperidino[3,2-g]coumarin, FD-25 9-Carboxy-1,2,4,5,3H,6H,10H-tetrahydro[1]benzopyrano[9,9a,1-gh]quinolizino-10-one, FD-26 N-Ethyl-4-trifluoromethylpiperidino[3,2-g].

Other dopants include salts of bis benzene sulphonic acid such as

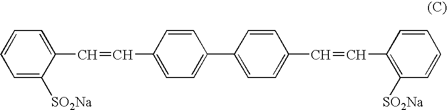

and perylene and perylene derivatives and dopants. Other dopants are dyes such as the fluorescent 4-dicyanomethylene-4H-pyrans and 4-dicyanomethylene-4H-thiopyrans, e.g. the fluorescent dicyanomethylenepyran and thiopyran dyes. Useful fluorescent dyes can also be selected from among known polymethine dyes, which include the cyanines, merocyanines, complex cyanines and merocyanines (i.e. tri-, tetra- and poly-nuclear cyanines and merocyanines), oxonols, hemioxonols, styryls, merostyryls, and streptocyanines. The cyanine dyes include, joined by a methine linkage, two basic heterocyclic nuclei, such as azolium or azinium nuclei, for example, those derived from pyridinium, quinolinium, isoquinolinium, oxazolium, thiazolium, selenazolium, indazolium, pyrazolium, pyrrolium, indolium, 3H-indolium, imidazolium, oxadiazolium, thiadioxazolium, benzoxazolium, benzothiazolium, benzoselenazolium, benzotellurazolium, benzimidazolium, 3H- or 1H-benzoindolium, naphthoxazolium, naphthothiazolium, naphthoselenazolium, naphthotellurazolium, carbazolium, pyrrolopyridinium, phenanthrothiazolium, and acenaphthothiazolium quaternary salts. Other useful classes of fluorescent dyes are 4-oxo-4H-benz-[d,e]anthracenes and pyrylium, thiapyrylium, selenapyrylium, and telluropyrylium dyes.

### Hole Transporting Materials

Where a hole transmitting layer is present, the hole transporting material can be an amine complex such as α-NPB, diaminoanthracene derivatives as disclosed in WO 2006/061594, poly(vinylcarbazole), N,N′-diphenyl-N,N′-bis(3-methylphenyl)-1,1′-biphenyl-4,4′-diamine (TPD), an unsubstituted or substituted polymer of an amino substituted aromatic compound, a polyaniline, substituted polyanilines, polythiophenes, substituted polythiophenes, polysilanes etc. Examples of polyanilines are polymers of

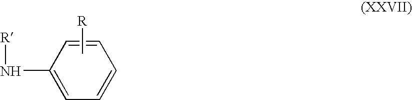

where R is in the ortho- or meta-position and is hydrogen, C1-18 alkyl, C1-6 alkoxy, amino, chloro, bromo, hydroxy or the group

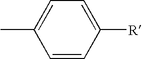

where R is alky or aryl and R′ is hydrogen, C1-6 alkyl or aryl with at least one other monomer of formula I above.

Or the hole transporting material can be a polyaniline, polyanilines which can be used in the present invention have the general formula

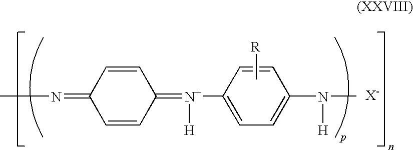

where p is from 1 to 10 and n is from 1 to 20, R is as defined above and X is an anion, preferably selected from Cl, Br, SO₄, BF₄, PF₆, H₂PO₃, H₂PO₄, arylsulphonate, arenedicarboxylate, polystyrenesulphonate, polyacrylate alkysulphonate, vinylsulphonate, vinylbenzene sulphonate, cellulose sulphonate, camphor sulphonates, cellulose sulphate or a perfluorinated polyanion.

Examples of arylsulphonates are p-toluenesulphonate, benzenesulphonate, 9,10-anthraquinone-sulphonate and anthracenesulphonate, an example of an arenedicarboxylate is phthalate and an example of arenecarboxylate is benzoate.

We have found that protonated polymers of the unsubstituted or substituted polymer of an amino substituted aromatic compound such as a polyaniline are difficult to evaporate or cannot be evaporated. However we have surprisingly found that if the unsubstituted or substituted polymer of an amino substituted aromatic compound is deprotonated the it can be easily evaporated i.e. the polymer is evaporable.

Preferably evaporable deprotonated polymers of unsubstituted or substituted polymer of an amino substituted aromatic compound are used. The de-protonated unsubstituted or substituted polymer of an amino substituted aromatic compound can be formed by deprotonating the polymer by treatment with an alkali such as ammonium hydroxide or an alkali metal hydroxide such as sodium hydroxide or potassium hydroxide. The degree of protonation can be controlled by forming a protonated polyaniline and de-protonating. Methods of preparing polyanilines are described in the article by A. G. MacDiarmid and A. F. Epstein, Faraday Discussions, Chem Soc., 88 P 319 1989. The conductivity of the polyaniline is dependant on the degree of protonation with the maximum conductivity being when the degree of protonation is between 40 and 60%, e.g. about 50% for example. Preferably the polymer is substantially fully deprotonated A polyaniline can be formed of octamer units i.e. p is four, e.g.

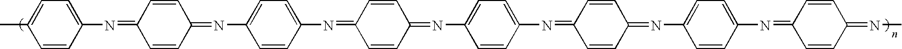

The polyanilines can have conductivities of the order of 1×10⁻¹ Siemen cm⁻¹ or higher. The aromatic rings can be unsubstituted or substituted e.g. by a C1 to 20 alkyl group such as ethyl.

The polyaniline can be a copolymer of aniline and preferred copolymers are the copolymers of aniline with o-anisidine, m-sulphanilic acid or o-aminophenol, or o-toluidine with o-aminophenol, o-ethylaniline, o-phenylene diamine or with amino anthracenes. Other polymers of an amino substituted aromatic compound which can be used include substituted or unsubstituted polyaminonapthalenes, polyaminoanthracenes, polyaminophenanthrenes, etc. and polymers of any other condensed polyaromatic compound. Polyaminoanthracenes and methods of making them are disclosed in U.S. Pat. No. 6,153,726. The aromatic rings can be unsubstituted or substituted e.g. by a group R as defined above.

Other hole transporting materials are conjugated polymer and the conjugated polymers which can be used can be any of the conjugated polymers disclosed or referred to in U.S. Pat. No. 5,807,627, WO 90/13148 and WO92/03490.

The preferred conjugated polymers are poly(p-phenylenevinylene)-PPV and copolymers including PPV. Other preferred polymers are poly(2,5 dialkoxyphenylene vinylene) such as poly(2-methoxy-5-(2-methoxypentyloxy-1,4-phenylene vinylene), poly(2-methoxypentyloxy)-1,4-phenylenevinylene), poly(2-methoxy-5-(2-dodecyloxy-1,4-phenylenevinylene) and other poly(2,5 dialkoxyphenylenevinylenes) with at least one of the alkoxy groups being a long chain solubilising alkoxy group, poly fluorenes and oligofluorenes, polyphenylenes and oligophenylenes, polyanthracenes and oligo anthracenes, ploythiophenes and oligothiophenes. In PPV the phenylene ring may optionally carry one or more substituents e.g. each independently selected from alkyl, preferably methyl, alkoxy, preferably methoxy or ethoxy. Any poly(arylenevinylene) including substituted derivatives thereof can be used and the phenylene ring in poly(p-phenylenevinylene) may be replaced by a fused ring system such as anthracene or naphthylene ring and the number of vinylene groups in each polyphenylenevinylene moiety can be increased e.g. up to 7 or higher.

The conjugated polymers can be made by the methods disclosed in U.S. Pat. No. 5,807,627, WO 90/13148 and WO 92/03490.

The structural formulae of some other hole transporting materials are shown in Figures Schemes 8-12, where R₁, R₂ and R₃ can be the same or different and are selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine or thiophenyl groups; R₁, R₂ and R₃ can also form substituted and unsubstituted fused aromatic, heterocyclic and polycyclic ring structures and can be copolymerisable with a monomer e.g. styrene. X is Se, S or O, Y can be hydrogen, substituted or unsubstituted hydrocarbyl groups, such as substituted and unsubstituted aromatic, heterocyclic and polycyclic ring structures, fluorine, fluorocarbons such as trifluoryl methyl groups, halogens such as fluorine or thiophenyl groups or nitrile. Examples of R₁ and/or R₂ and/or R₃ include aliphatic, aromatic and heterocyclic alkoxy, aryloxy and carboxy groups, substituted and substituted phenyl, fluorophenyl, biphenyl, phenanthrene, anthracene, naphthyl and fluorene groups alkyl groups such as t-butyl, heterocyclic groups such as carbazole.

The thickness of the hole transporting layer is preferably 20 nm to 200 nm.
The polymers of an amino substituted aromatic compound such as polyanilines referred to above can also be used as buffer layers with or in conjunction with other hole transporting materials.

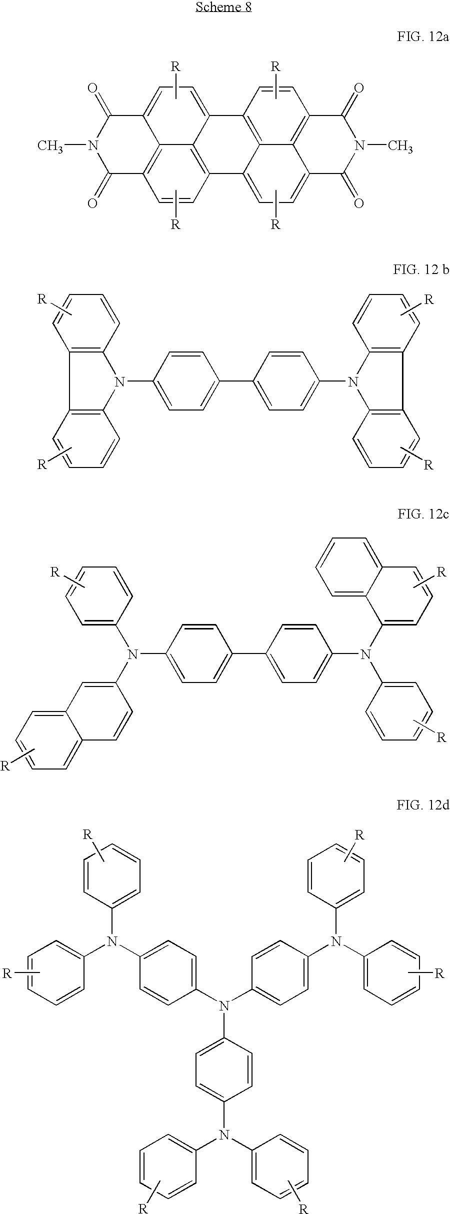

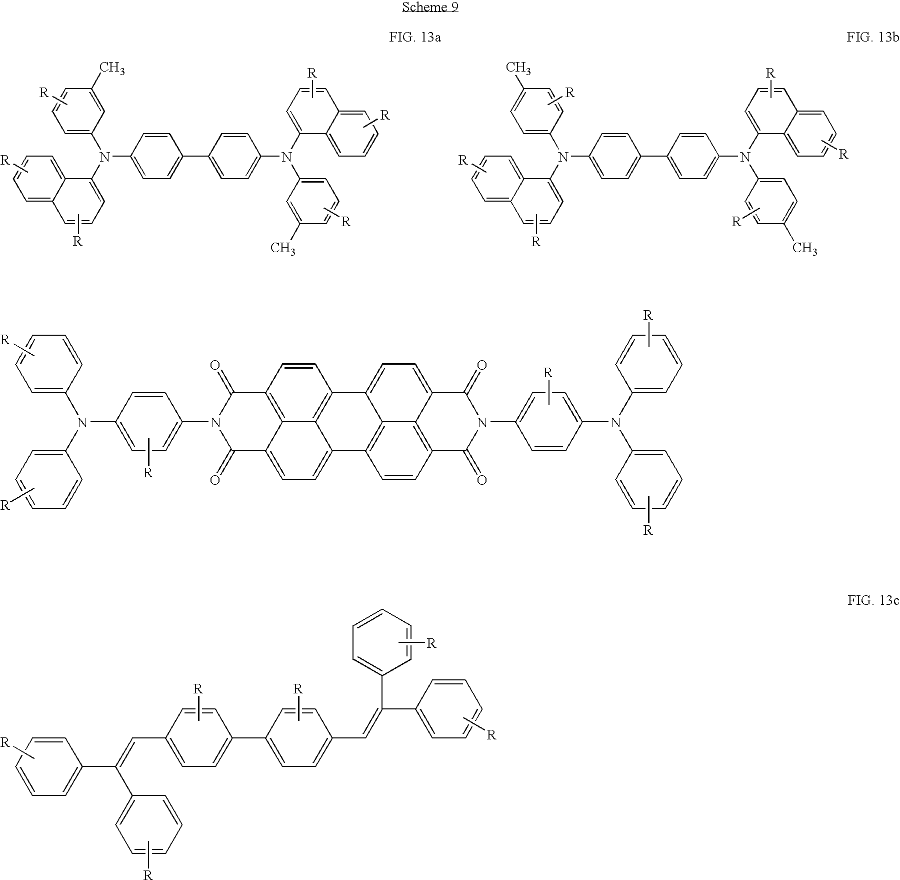

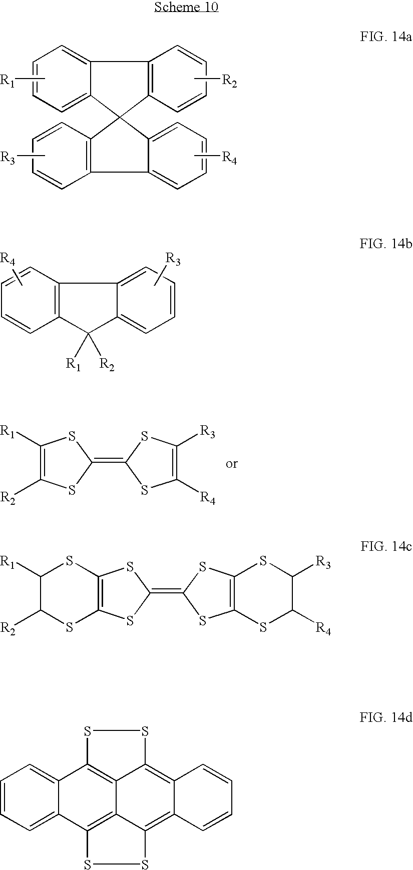

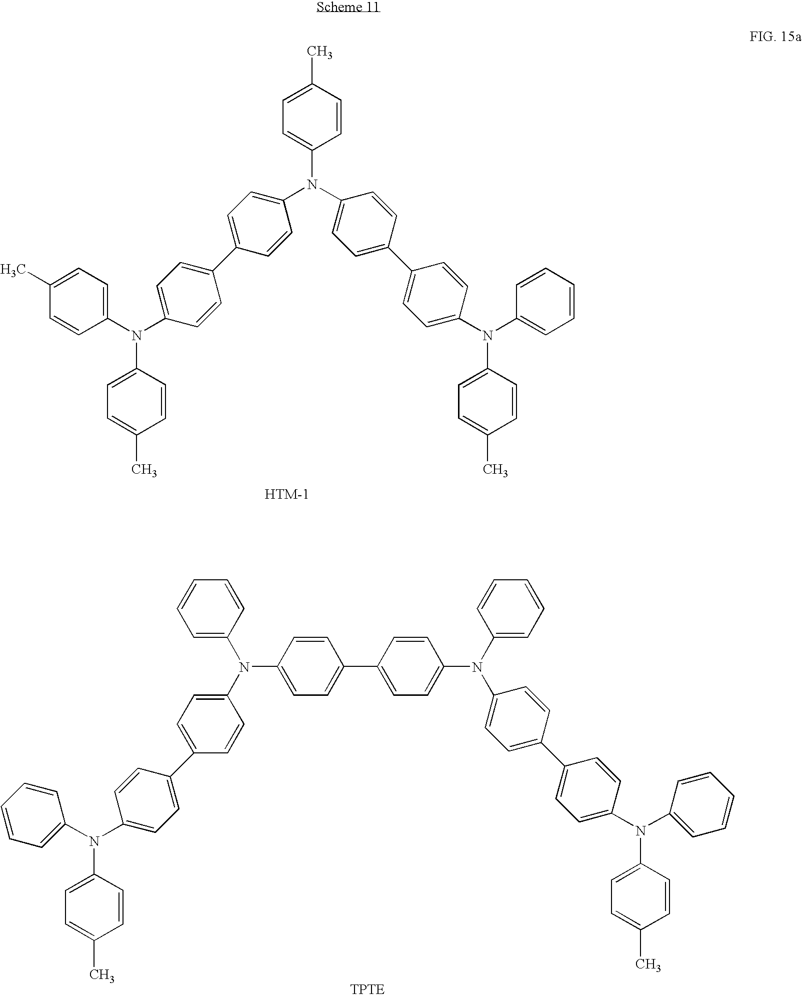

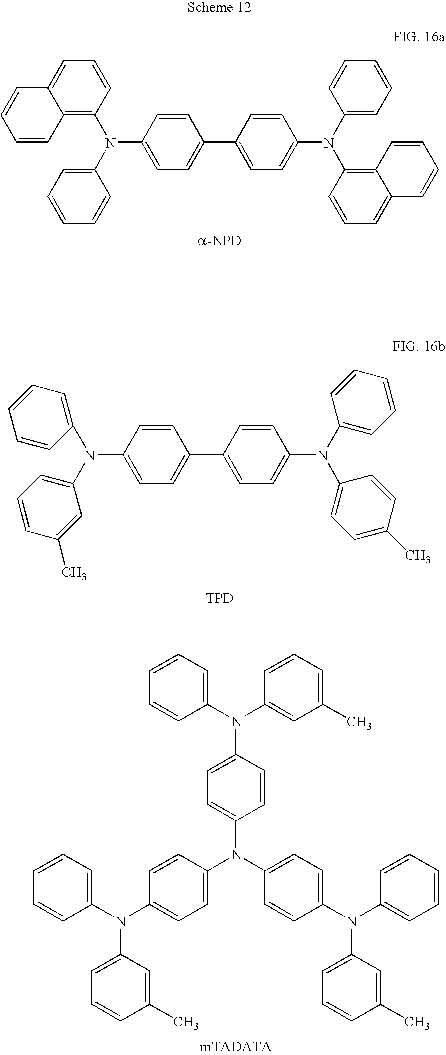

### Electron Transporting Materials

An electron injecting material is a material which will transport electrons when an electric current is passed through electron injecting materials include a metal complex such as a metal quinolate e.g. an aluminium quinolate, lithium quinolate, a cyano anthracene such as 9,10 dicyano anthracene, cyano substituted aromatic compounds, tetracyanoquinidodimethane a polystyrene sulphonate or a compound with the structural formulae shown in Schemes 13 and 14 in which the phenyl rings can be substituted with substituents R as defined above.

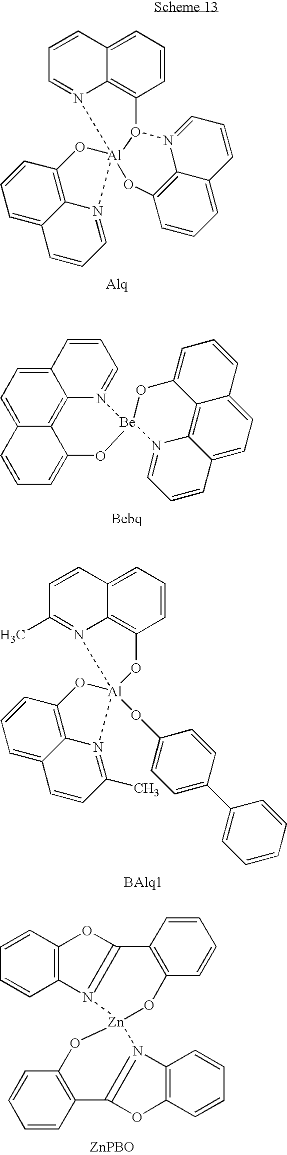

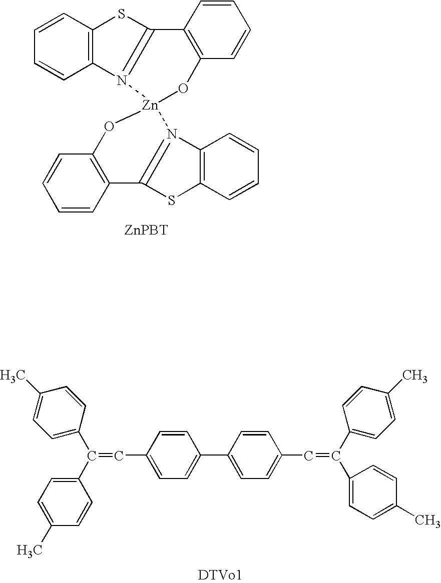

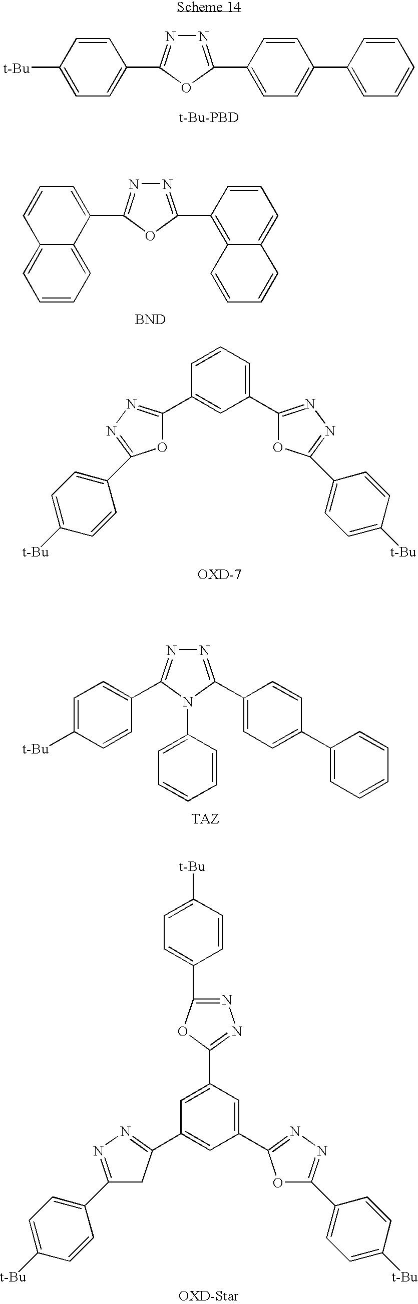

### PREPARATIVE EXAMPLE 1

### Synthesis of the bis(quin-8-olate)copper Complex (Cuq₂)

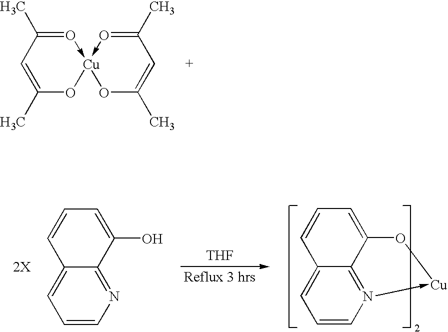

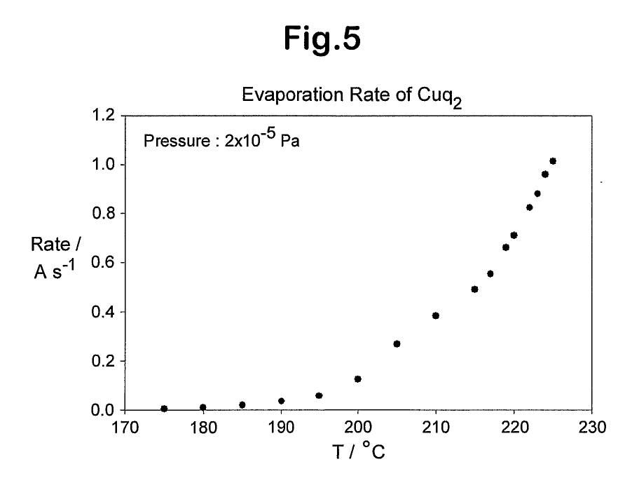

A solution of 8-hydroxyquinoline (5.92 g, 40.76 mmol) in THF (50 mL) was added to a stirred suspension of copper(II) acetylacetonate (5.01 g, 19.13 mmol) in THF (100 mL). A brown suspension was immediately observed and was refluxed for three hours. The brown solid was filtered off, washed thoroughly with THF and dried in the vacuum oven for 8 hours at 80° C., giving 6.2 g of product (92% yield). Sublimation (290° C., 10⁻⁶ Torr.) yielded an analytical sample (5.7 g from 6.2 g); melting point at 339° C. (DSC peak). The in vacuo evaporation rate of this compound is as shown in FIG. 5 which shows the rate of film deposition in Å/s⁻¹ against deposition temperature at a pressure of 2×10⁻⁵ Pa.

| | | |
|---|---|---|
| Anal. | Cald. for C₁₈H₁₂N₂O₂Cu | C, 61.45; H, 3.44; N, 7.96 |
| | Found | C, 61.23; H, 3.38; N, 7.80 |

### PREPARATIVE EXAMPLE 2

### Synthesis of the bis(quin-8-olate)vanadyl Complex (VOq₂)

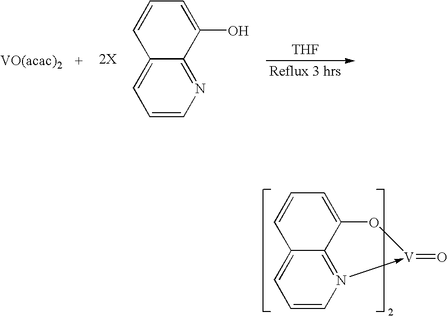

A solution of 8-hydroxyquinoline (5.90 g, 40.64 mmol) in THF (50 mL) was added to a stirred solution of vanadyl(IV) acetylacctonate (5.02 g, 18.94 mmol) in THF (80 mL). A brown suspension was immediately observed and was refluxed for three hours. The brown solid was filtered off, washed thoroughly with THF and dried in the vacuum oven for 8 hours at 80° C., giving 4.77 g of product (71% yield). Sublimation (295° C., 10⁻⁶ Torr.) yielded an analytical sample (4.2 g from 4.7 g); melting point at 350° C. (DSC peak) and Tg at 151° C.

| | | |
|---|---|---|
| Anal. | Cald. for C₁₈H₁₂N₂O₃V | C, 60.86; H, 3.41; N, 7.89 |
| | Found | C, 60.37; H, 3.31; N, 7.74 |

### PREPARATIVE EXAMPLE 3

### Vananadyl 2,9,16,23-tetraphenoxy-29H,31H-phthalocyanine Complex

This compound (VOTPOPc) was purchased from Aldrich, catalogue number 41, 438-7, CAS number, [109738-21-8] and purified by sublimation (once) before use.

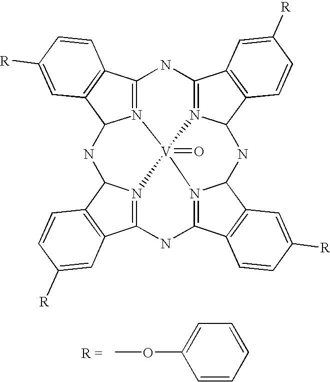

### PREPARATIVE EXAMPLE 4

### Device Structure

A pre-etched ITO coated glass piece (10×10 cm²) was used. The device was fabricated by sequentially forming layers on the ITO, by vacuum evaporation using a Solciet Machine, ULVAC Ltd. Chigacki, Japan. The active area of each pixel was 3 mm by 3 mm. The coated electrodes were encapsulated in an inert atmosphere (nitrogen) with V-curable adhesive using a glass back plate. Electroluminescence studies were performed with the ITO electrode was always connected to the positive terminal. The current vs. voltage studies were carried out on a computer controlled Keithly 2400 source meter.

### EXAMPLE 1

Devices were formed by the method described above consisting of:

### ITO/ZnTP TP (20)/α-NBP(75)/AlQ₃.DPQA (75:0.2)/ZrQ4 (20)/KL(x)/LiF(0.3)/Al

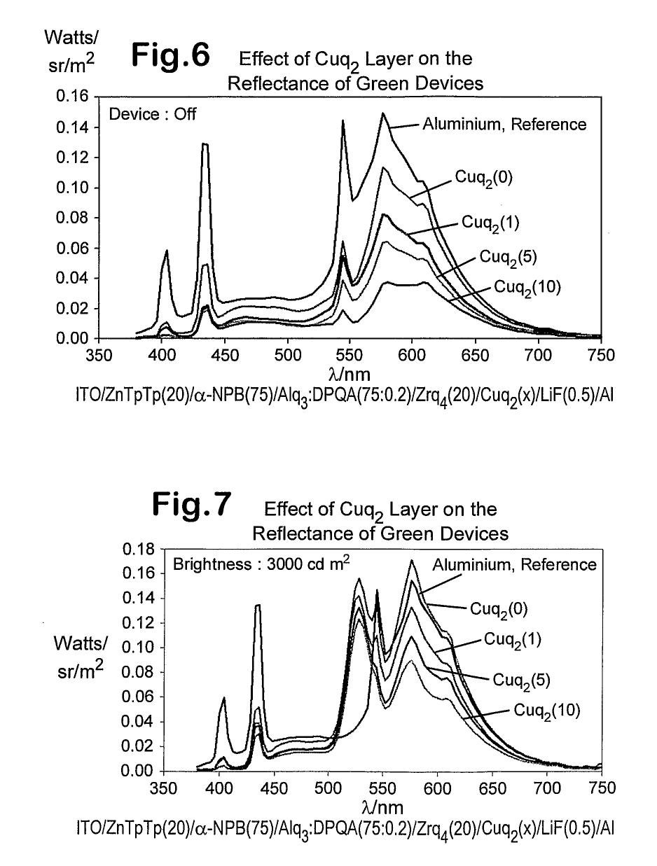

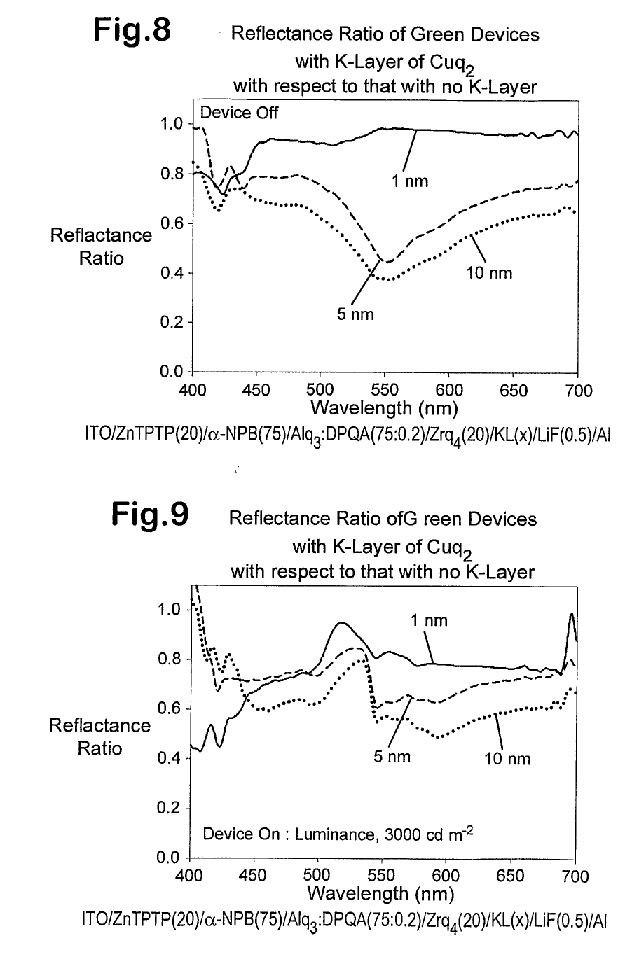

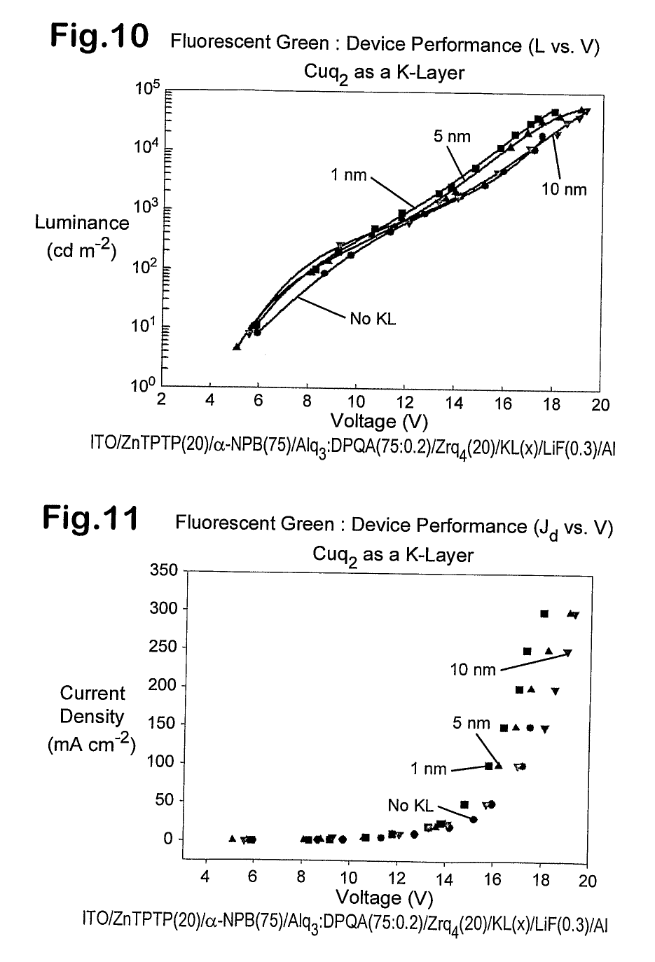

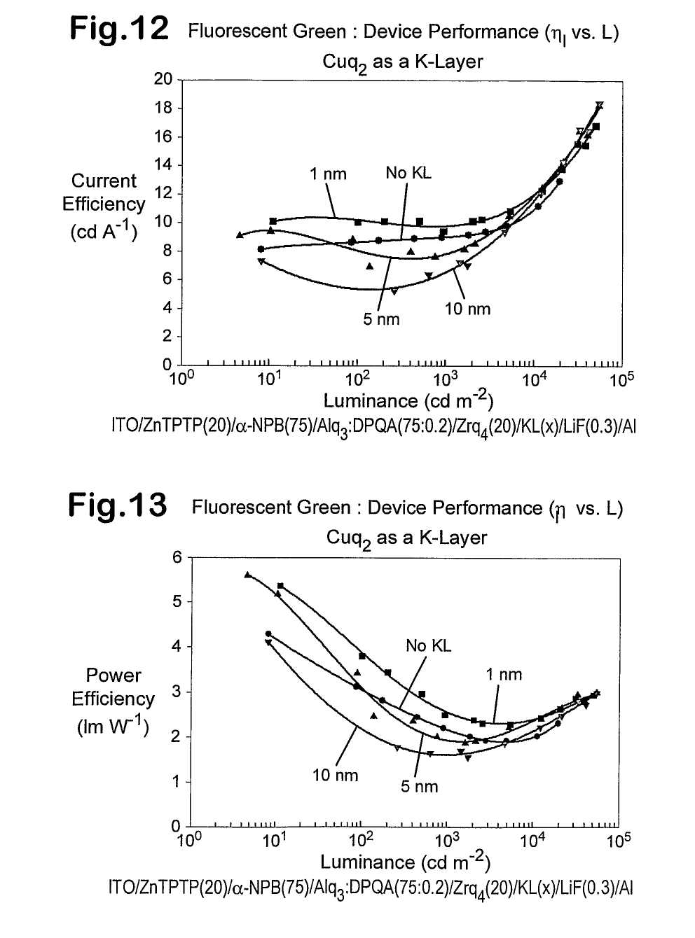

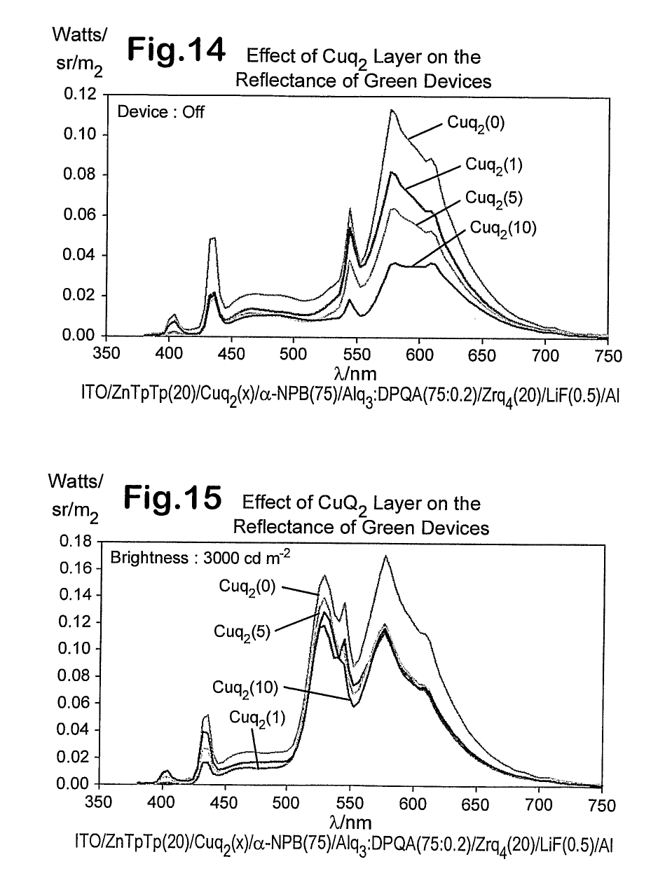

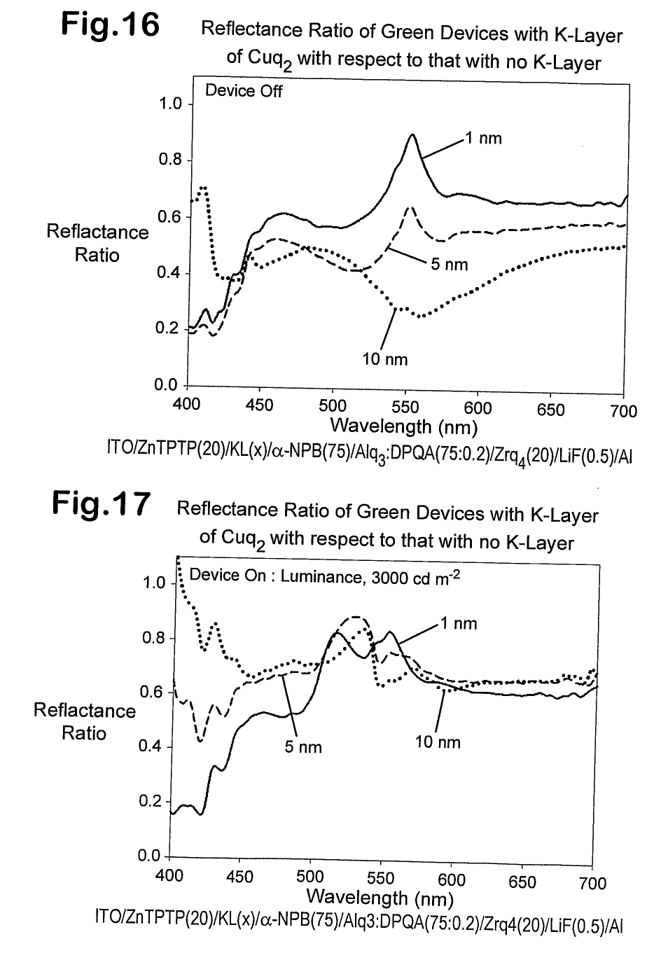

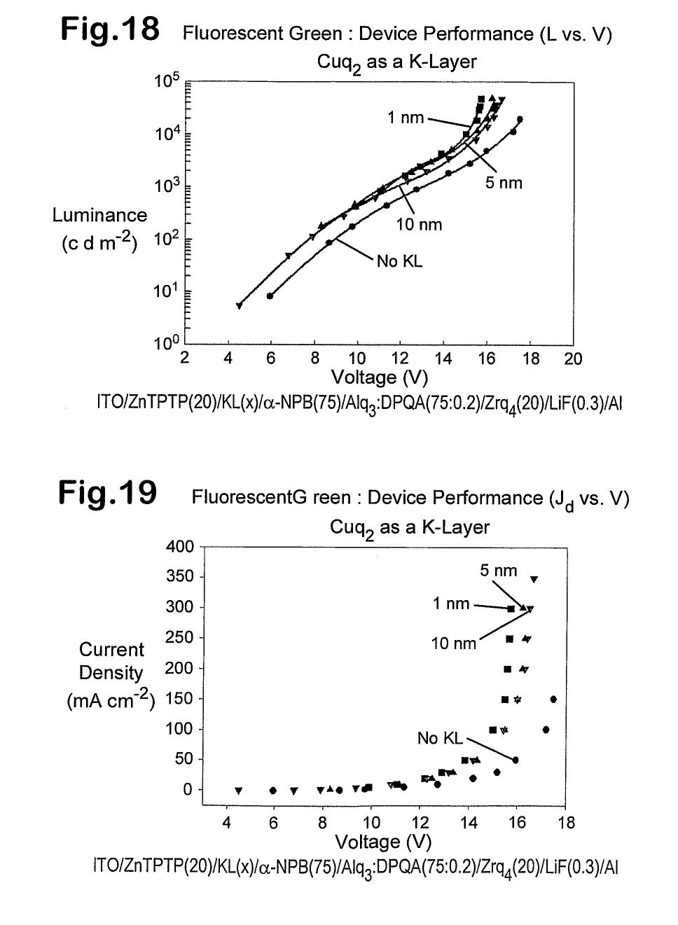

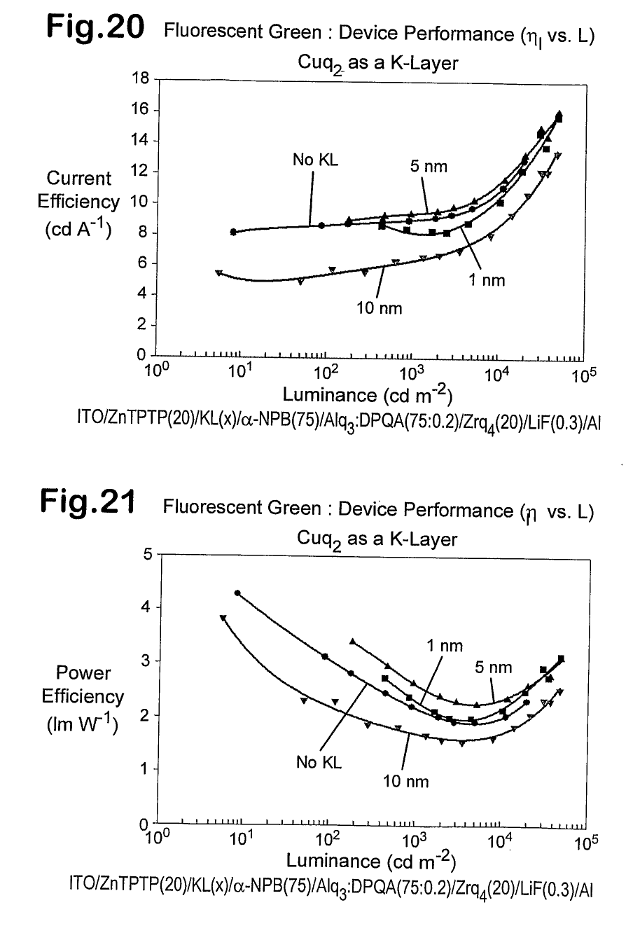

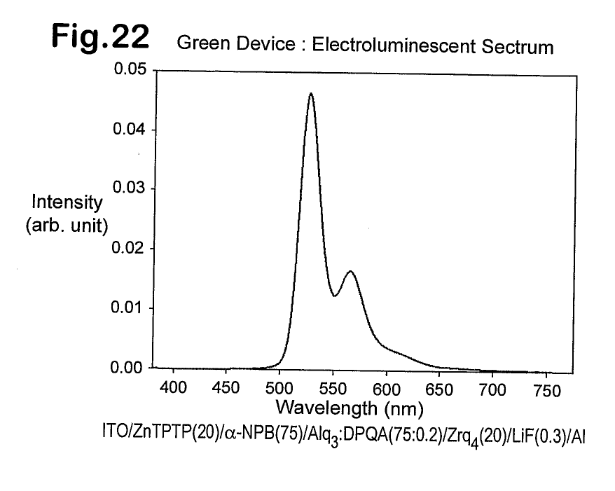

### ITO/ZnTP TP (20)/KL(x)/α-NBP(75)/AlQ₃.DPQA (75:0.2)/ZrQ₄(20)/LiF(0.3)/Al

wherein ZnTP TP represents zinc phthalocyanine of formula indicated below, α-NBP has the structure indicated below, and KL(X) indicates CuQ₂ in the thickness in nm indicated. The performance of the devices was measured and the results are as shown in FIGS. 5-21. A spectrum of a similar cell without CuQ₂ is shown at FIG. 22. Note in relation to the thicknesses of the LiF that the quoted value is sometimes 0.3 nm and sometimes 0.5 nm, no significance flowing from that difference which is within experimental error.

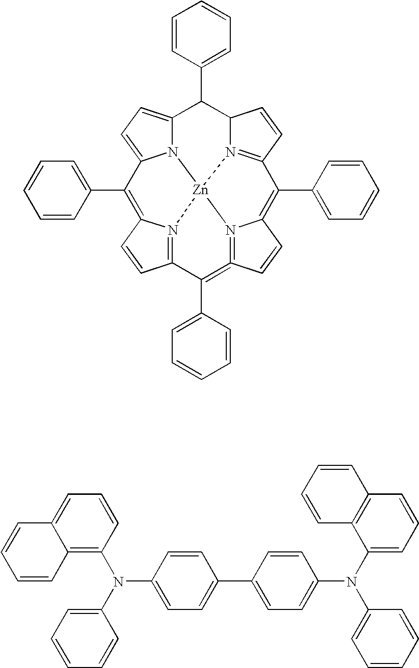

### EXAMPLE 2

Devices were formed by the method described above consisting of:

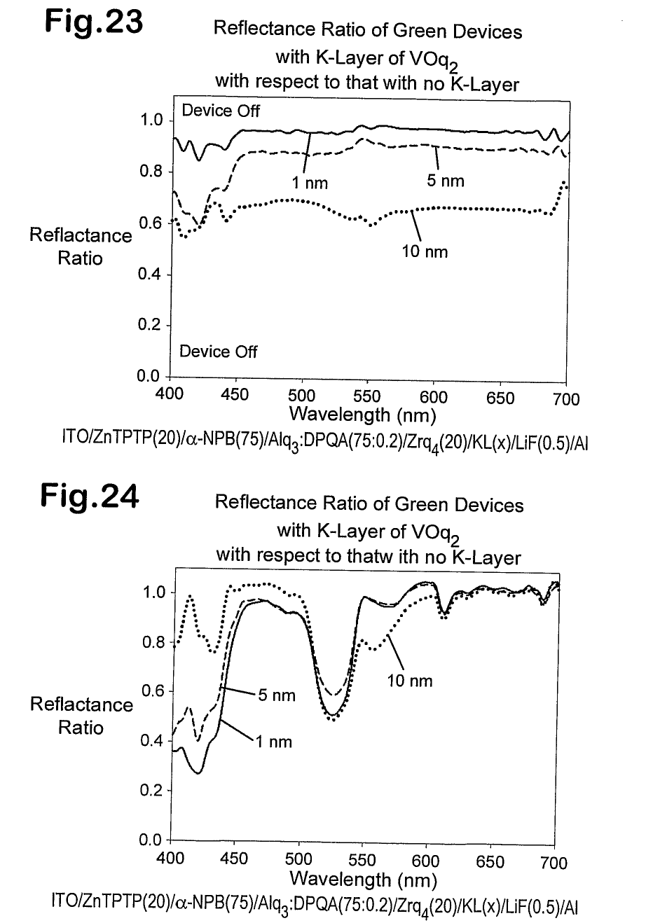

### ITO/ZnTP TP (20)/α-NBP(75)/AlQ₃.DPQA (75:0.2)/Zrq₄ (20)/KL(x)/LiF(0.3)/Al

in which in this instance KL(x) represents VOq₂. The performance of the devices was measured and the results are as shown in FIGS. 23-24.

### EXAMPLE 3

Devices were formed by the method described above consisting of:

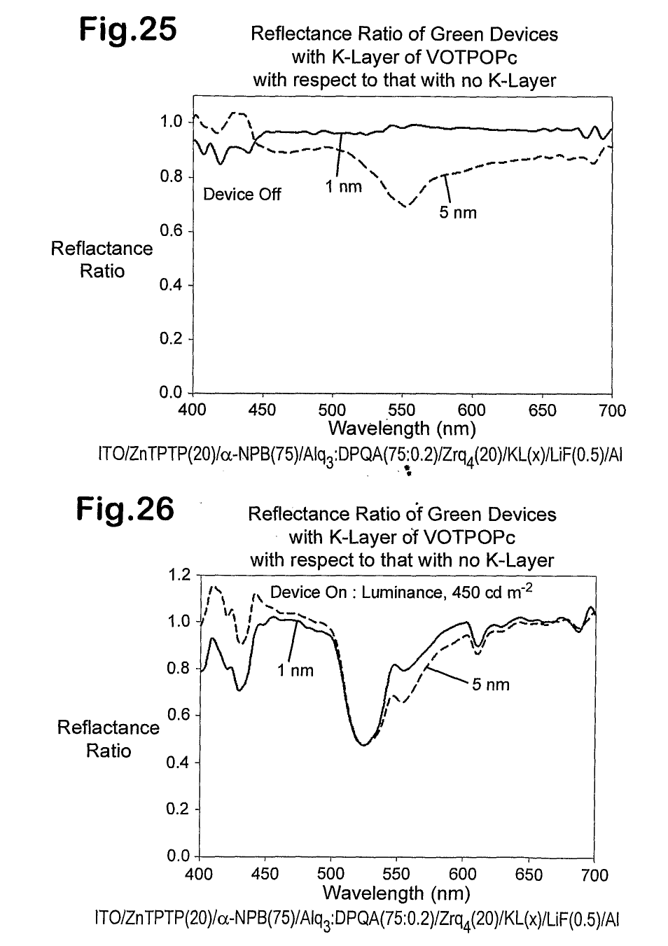

### ITO/ZnTP TP (20)/α-NBP(75)/AlQ_{z}.DPQA (75:0.2)/Zrq₄ (20)//KL(x)/LiF(0.3)/Al

in which in this instance KL(x) represents VOTPOPc. The performance of the devices was measured and the results are as shown in FIGS. 25-26.

1.-53. (canceled)

54. An electroluminescent device which comprises:
(i) a transparent first electrode;
(ii) a second electrode; and
(iii) a layer of an electroluminescent material between said first electrode and said second electrode; and
wherein there is also a layer of a reflectivity influencing material between one of the electrodes and the layer of electroluminescent material and in which the reflectivity influencing material is a sublimable compound.

55. An electroluminescent device according to claim 54, wherein the first electrode is selected from the group consisting of a transparent conductive glass, a transparent plastics material, a conductive polymer, a conductive polymer coated glass, and a conductive polymer coated plastics material.

56. An electroluminescent device according to claim 54, wherein the electroluminescent material is selected from the group consisting of:
(a) an electroluminescent organic polymer;
(b) a host doped with a fluorescent or phosphorescent material;
(c) a metal complex;
(d) an organometallic compound;
(e) a conjugated aromatic small molecule;
(f) a metal quinolate;
(g) a non rare earth metal complex;
(h) a P-diketone complex; and,
(i) a member selected from the group consisting of Al(DBM)₃, Zn(DBM)₂, Mg(DBM)₂, and Sc(DBM)₃, wherein (DBM) is tris-1,3-diphenyl-1-3-propanedione).

57. An electroluminescent device according to claim 54 wherein the electroluminescent material is an organometallic complex selected from the group consisting of:
(a) an organometallic complex having the general chemical formula 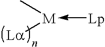
where: Lα and Lp are organic ligands; M is a rare earth substance, a transition metal, a lanthanide series substance, or an actinide series substance; and n is the valence state of the metal M; and in which the ligands Lα are the same or different, and wherein there is optionally a plurality of ligands Lp which can be the same or different;
(b) an organometallic complex having the general chemical formula (Lₙ)ₙM₁M₂ or (Lₙ)ₙM₁M₂(Lₚ) where: Lₙ is Lα; Lₚ is a neutral ligand; M₁ is a rare earth substance, a transition metal, a lanthanide series substance, or an actinide series substance; M₂ is a non rare earth metal; and n is the combined valence state of M₁ and M₂; and
(c) a binuclear, trinuclear or polynuclear organometallic complex having the general chemical formula
(Lm)ₓM₁M₂←(Ln)_{y} (i)
or 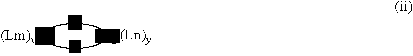
where in formulas (i) and (ii): L is a bridging ligand; M₁ is a rare earth metal; M₂ is M₁ or a non rare earth metal; Lm and Ln are the same or different organic ligands; Lα is as defined above; and x is the valence state of M₁ and y is the valence state of M₂;
or having the general chemical formula 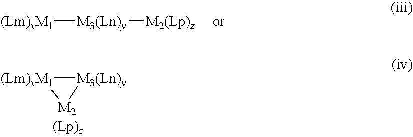
where in formulas (iii) and (iv): M₁, M₂ and M₃ are the same or different rare earth metals; Lm, Ln and Lp are organic ligands Lα; x is the valence state of M₁; y is the valence state of M₂; z is the valence state of M₃; and Lp can be the same as Lm and Ln or different;
or having the general chemical formula 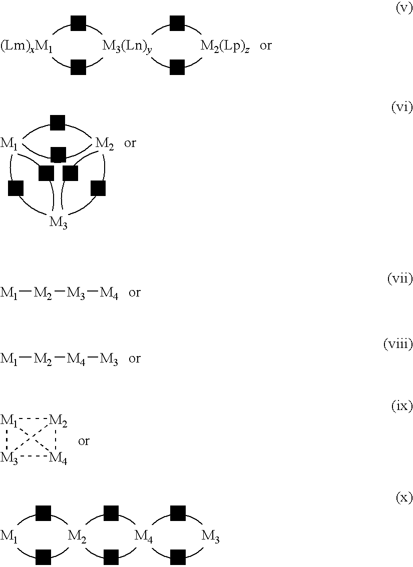
where in formulas (v) to (x): M₄ is M₁ and L is a bridging ligand and in which the rare earth metals and the non rare earth metals can be joined together by a metal-to-metal bond and/or via an intermediate bridging atom, ligand or molecular group, or in which there are more than three metals joined by metal-to-metal bonds and/or joined via intermediate ligands; the non-rare earth metal being selected from lithium, sodium, potassium, rubidium, caesium, beryllium, magnesium, calcium, strontium, barium, copper, silver, gold, zinc, cadmium, boron, aluminium, gallium, indium, germanium, tin, antimony, lead, and metals of the first, second and third groups of transition metals, and the rare earth or transition metal is selected from Sm(III), Eu(II), Eu(III), Tb(III), Dy(III), Yb(III), Lu(III), Gd(III), Gd(III) U(III), Tm(III), Ce(III), Pr(III), Nd(III), Pm(III), Dy(III), Ho(III) and Er(III).

58. An electroluminescent device according to claim 57 wherein, in chemical formulas (c) (v) to (c) (x), the metals of the first, second and third groups of transition metals are selected from the group consisting of: manganese, iron, ruthenium, osmium, cobalt, nickel, palladium, platinum, cadmium, chromium, titanium, vanadium, zirconium, tantalum, molybdenum, rhodium, iridium, titanium, niobium, scandium, and yttrium.

59. An electroluminescent device according to claim 57 wherein Lα is selected from any of the formulae (IV) to (XVII) herein, and Lp is selected from any of the formulae in Schemes 1-7 herein or formulae (XVIII) to (XXV) herein.

60. An electroluminescent device according to claim 56 wherein the electroluminescent material (f) is lithium quinolate.

61. An electroluminescent device according to claim 56 wherein the electroluminescent material (g) is a complex selected from the group consisting of aluminum, magnesium, zinc and scandium complexes.

62. An electroluminescent device according to claim 54, wherein the second electrode is aluminum, calcium, lithium, or a silver/magnesium alloy.

63. An electroluminescent device according to claim 54, wherein the reflectivity influencing material is semi-transparent.

64. An electroluminescent device according to claim 54, wherein the reflectivity influencing material is selected from the group consisting of:
(a) copper quinolate (Cuq₂);
(b) VOq₂;
(c) VOTPOPc;
(d) metal complexes having the general chemical formula M(DBM)ₓ, where: M is a transition metal; x is the valence state of M; and DBM is dibenzoyl methane;
(e) metal fluorides;
(f) metal phthalocyanines;
(g) metal complexes comprising C60 where C60 refers to a so-called buckminsterfullerene or “buckyball” material;
(h) metal complexes of tetracyanoquinidodimethane;
(i) metal quinolates of the chemical formula Mqₙ, where M is a metal or metal oxide and n is the valency of M; and,
(j) rare earth quinolate complexes.

65. An electroluminescent device according to claim 64, wherein the metal complex (d) includes a transition metal M selected from the group consisting of chromium, copper, tin (II), tin(IV), lead, palladium, platinum, and nickel.

66. An electroluminescent device according to claim 64, wherein the metal phthalocyanine (f) is selected from the group consisting of lithium, copper, magnesium, barium, titanyl, vanadyl and zirconyl phthalocyanine.

67. An electroluminescent device according to claim 64, wherein the buckminsterfullerene material (g) is selected from the group consisting of manganese, magnesium, calcium, barium, sodium, potassium, rubidium, and caesium C60 compounds.

68. An electroluminescent device according to claim 64, wherein the metal quinolate (i) includes a metal or metal oxide M selected from the group consisting of Sn(II), Sn(IV), Cr(I), and NbO.

69. An electroluminescent device according to claim 64, wherein the rare earth quinolate complex (j) is selected from the group consisting of Euq₃(bathophenanthroline) and Euq₃(phenanthroline).

70. An electroluminescent device according to claim 54, wherein the layer of reflectivity influencing material is separated from the layer of electroluminescent material by at least one intervening layer.

71. An electroluminescent device according to claim 54, wherein there is a layer of a hole transport material between one of said electrodes and the electroluminescent layer, further wherein one of the following applies:
(a) the hole transport material and a light emitting metal compound are mixed to form one layer;
(b) the hole transport material comprises α-NBP;
(c) the hole transport material comprises an aromatic amine complex;
(d) the hole transport material comprises a film of a polymer selected from the group consisting of: poly(vinylcarbazole); N,N′-diphenyl-N,N′-bis(3-methylphenyl)-1,1′-biphenyl-4,4′-diamine (TPD); polyaniline; substituted polyanilines; polythiophenes; substituted polythiophenes; polysilanes; and substituted polysilanes;
(e) the hole transport material comprises a film of a compound of formula (II) or (III) herein or as in Scheme 8-12 above;
(f) the hole transport material comprises a conjugated polymer which is one of the following: (i) a poly(arylenevinylene) or a substituted derivative thereof, or is selected from poly(p-phenylenevinylene)-PPV and copolymers including PPV, the phenylene ring optionally carrying one or more substituents, the phenylene ring in poly(p-phenylenevinylene) optionally being replaced by a fused ring system such as anthracene or naphthalene ring, the number of vinylene groups in each polyphenylenevinylene moiety optionally being greater than 1; (ii) a material selected from poly(2,5 dialkoxyphenylene vinylene), poly(2-methoxy-5-(2-methoxypentyloxy-1,4-phenylenevinylene), poly(2-methoxypentyloxy)-1,4-phenylenevinylene), poly(2-methoxy-5-(2-dodecyloxy-1,4-phenylenevinylene) and other poly(2,5 dialkoxyphenylenevinylenes) with at least one of the alkoxy groups being a long chain solubilising alkoxy group; or (iii) an amino substituted aromatic compound which is optionally deprotonated and is optionally evaporable and is a copolymer of an aniline monomer of the general chemical formula 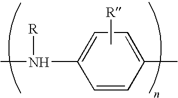
where: R is in the ortho- or meta-position and is selected from hydrogen, C1-18 alkyl, C1-6 alkoxy, amino, chloro, bromo, hydroxy and the group 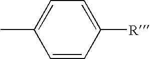
where R″ is alky or aryl and R′″ is hydrogen, C1-6 alkyl or aryl, with at least one other monomer of formula I above, the copolymer having the general chemical formula 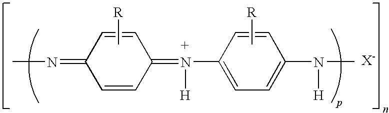
where: p is an integer from 1 to 10; n is an integer from 1 to 20; R is hydrogen, C1-18 alkyl, C1-6 alkoxy, amino, chloro, bromo, or hydroxy; or p is an integer from 1 to 20 and n is an integer from 1 to 50; and X is an anion having a weight average molecular weight on the order of 30,000, p optionally being four, and X optionally being selected from Cl, Br, SO₄, BF₄, PF₆, H₂PO₃, H₂PO₄, arylsulphonate, arenedicarboxylate, polystyrenesulphonate, polyacrylate alkysulphonate, vinylsulphonate, vinylbenzene sulphonate, cellulose sulphonate, cellulose sulphate or a perfluorinated polyanion;
(g) a compound having the general chemical formula 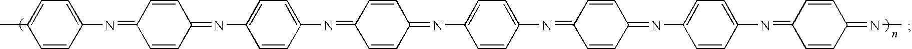
(h) a copolymer of aniline with o-anisidine, m-sulphanilic acid or o-aminophenol, or o-toluidine with o-aminophenol, o-ethylaniline or o-phenylene diamine; and,
(i) a polymer selected from the group consisting of substituted or unsubstituted polyaminonapthalenes, polyaminoanthracenes, and polyamino phenanthrenes.

72. An electroluminescent device according to claim 54, wherein there is a layer of an electron transport material between the cathode and the light absorbing material layer, the electron transport material optionally being selected from metal quinolates, a cyano-anthracene, 9,10 dicyano-anthracene, a polystyrene-sulphonate, aluminium quinolate and lithium quinolate or has a formula as shown in Scheme 13 above.

73. An electroluminescent device according to claim 72, wherein the electron transport material is zirconium quinolate.
